(19) United States
(12) Patent Application Publication
(10) Pub. No.: US 2025/0021712 A1
(43) Pub. Date: Jan. 16, 2025

(54) Systems and Methods for Performing Autonomous Navigation

(71) Applicant: Vayu Robotics, Inc., Palo Alto, CA (US)

(72) Inventors: Anand GOPALAN, Foster City, CA (US); Nitish SRIVASTAVA, Cupertino, CA (US); Mahesh KRISHNAMURTHI, Saratoga, CA (US); Huaijin CHEN, Belmont, CA (US); Rajanatha SHETTIGARA, San Jose, CA (US); Jason Louis ASHTON, Mountain View, CA (US); Adwait Jayant GANDHE, Santa Clara, CA (US); Hesam RABETI, Palo Alto, CA (US); Vinaykumar Subrahmanya HEGDE, San Jose, CA (US); Peter Jans GILLESPIE, Redwood City, CA (US); Arian HOUSHMAND, Redwood City, CA (US)

(73) Assignee: Vayu Robotics, Inc., Palo Alto, CA (US)

(21) Appl. No.: 18/416,820

(22) Filed: Jan. 18, 2024

Related U.S. Application Data
(60) Provisional application No. 63/480,461, filed on Jan. 18, 2023.

(51) Int. Cl. G06F 30/15; G06F 30/27

(52) U.S. Cl. CPC G06F 30/15; G06F 30/27

(57) ABSTRACT

Systems and techniques performing autonomous navigation are illustrated. One embodiment includes a method for navigation. The method inputs a set of sensor data obtained from a plurality of sensors into at least one convolutional neural network (CNN). The at least one CNN generates a plurality of key-value pairs where each the key-value pair corresponds to an individual sensor from the plurality of sensors; and a value included in the key-value pair is determined based upon a subset of sensor data obtained from the individual sensor. The method inputs at least one navigation query and the plurality of key-value pairs into a Cross-Attention Transformer (CAT). The method obtains, from the CAT, a set of weighted sums, wherein each weighted sum corresponds to: a certain key-value pair; and a certain sensor from the plurality of sensors. The method updates a model depicting a 3D environment based on the set of weighted sums.

### CROSS-REFERENCE TO RELATED APPLICATIONS

The current application claims the benefit of and priority under 35 U.S.C. § 119(e) to U.S. Provisional Patent Application No. 63/480,461 entitled “Systems and Methods for Performing Autonomous Navigation” filed Jan. 18, 2023. The disclosure of U.S. Provisional Patent Application No. 63/480,461 is hereby incorporated by reference in its entirety for all purposes.

### FIELD OF THE INVENTION

The present invention generally relates to autonomous navigation systems and, more specifically, sensor organization, attention network arrangement, and simulation management.

### BACKGROUND

Autonomous vehicles are vehicles that can be operated independently, utilizing sensors such as cameras to update knowledge of their environment in real-time, and enabling navigation with minimal additional input from users. Autonomous vehicles can be applied to various areas related to the transportation of people and/or items.

### SUMMARY OF THE INVENTION

Systems and techniques for performing autonomous navigation are illustrated. One embodiment includes a system for navigation, the system including: a processor; memory accessible by the processor; and instructions stored in the memory that when executed by the processor direct the processor to perform various actions. The processor is directed to obtain, from a plurality of sensors, a set of sensor data. The processor is directed to input the set of sensor data obtained from the plurality of sensors into at least one convolutional neural network (CNN). The at least one CNN generates a plurality of key-value pairs and for each key-value pair from the plurality of key-value pairs: the key-value pair corresponds to an individual sensor from the plurality of sensors; and a value included in the key-value pair is determined based upon a subset of sensor data, from the set of sensory data, wherein the subset of sensor data was obtained from the individual sensor. The processor is directed to retrieve at least one navigation query. The processor is directed to input the at least one navigation query and the plurality of key-value pairs into a Cross-Attention Transformer (CAT). The processor is directed to obtain, from the CAT, a set of weighted sums, wherein each weighted sum from the set of weighted sums corresponds to: a certain key-value pair from the plurality of key-value pairs; and a certain sensor from the plurality of sensors. The processor is directed to update a model based on the set of weighted sums, wherein the model depicts a three-dimensional (3D) environment surrounding the system. The processor is directed to navigate the system within the 3D environment according, at least in part, to the model.

In a further embodiment, for each key-value pair from the plurality of key-value pairs, the key-value pair further corresponds to a particular location within the 3D environment.

In another embodiment, a sensor of the plurality of sensors is selected from the group including: an inertial measurement unit (IMU), an inertial navigation system (INS), a global navigation satellite system (GNSS), a camera, a proximity sensor, and a light detection and ranging system (LiDARs).

In another embodiment, the plurality of sensors includes at least one camera; the plurality of sensors obtains the set of sensor data from a plurality of perspectives; and the set of sensor data includes an accumulated image.

In a further embodiment, generating the plurality of key-value pairs includes: calibrating the at least one camera; deriving a positional embedding from the calibration and a patch, wherein the patch includes a subsection of the accumulated image; obtaining, from the at least one CNN, an output feature representation; and concatenating the positional embedding and the output feature representation.

In another embodiment, the system is an autonomous vehicle.

In still another embodiment, the at least one navigation query includes at least one of: a first query, wherein the first query represents a static two-dimensional grid depicting a first subarea of the 3D environment; or a second query, wherein the second query represents a static three-dimensional grid depicting a second subarea of the 3D environment. In a further embodiment, updating the model includes at least one of: identifying potential obstacles that could impede navigation using the first query; or localizing subsets of the second subarea that are occupied using the second query.

In another embodiment, inputting the at least one navigation query and the plurality of key-value pairs into the CAT includes converting the at least one navigation query into a query input using a temporal self-attention transformer.

In another embodiment, updating the model based on the set of weighted sums includes deriving, from the set of weighted sums a set of depth estimates corresponding to the 3D environment; and deriving, from the set of depth estimates, a depth map for the 3D environment.

One embodiment includes a method for navigation. The method obtains, from a plurality of sensors, a set of sensor data. The method inputs the set of sensor data obtained from the plurality of sensors into at least one convolutional neural network (CNN). The at least one CNN generates a plurality of key-value pairs and for each key-value pair from the plurality of key-value pairs: the key-value pair corresponds to an individual sensor from the plurality of sensors; and a value included in the key-value pair is determined based upon a subset of sensor data, from the set of sensor data, wherein the subset of sensor data was obtained from the individual sensor. The method retrieves at least one navigation query. The method inputs the at least one navigation query and the plurality of key-value pairs into a Cross-Attention Transformer (CAT). The method obtains, from the CAT, a set of weighted sums, wherein each weighted sum from the set of weighted sums corresponds to: a certain key-value pair from the plurality of key-value pairs; and a certain sensor from the plurality of sensors. The method updates a model based on the set of weighted sums, wherein the model depicts a three-dimensional (3D) environment surrounding a system. The method navigates the system within the 3D environment according, at least in part, to the model.

In a further embodiment, for each key-value pair from the plurality of key-value pairs, the key-value pair further corresponds to a particular location within the 3D environment.

In another embodiment, a sensor of the plurality of sensors is selected from the group including: an inertial measurement unit (IMU), an inertial navigation system (INS), a global navigation satellite system (GNSS), a camera, a proximity sensor, and a light detection and ranging system (LiDARs).

In another embodiment, the plurality of sensors includes at least one camera; the plurality of sensors obtains the set of sensor data from a plurality of perspectives; and the set of sensor data includes an accumulated image.

In a further embodiment, generating the plurality of key-value pairs includes: calibrating the at least one camera; deriving a positional embedding from the calibration and a patch, wherein the patch includes a subsection of the accumulated image; obtaining, from the at least one CNN, an output feature representation; and concatenating the positional embedding and the output feature representation.

In another embodiment, the system is an autonomous vehicle.

In still another embodiment, the at least one navigation query includes at least one of: a first query, wherein the first query represents a static two-dimensional grid depicting a first subarea of the 3D environment; or a second query, wherein the second query represents a static three-dimensional grid depicting a second subarea of the 3D environment. In a further embodiment, updating the model includes at least one of: identifying potential obstacles that could impede navigation using the first query; or localizing subsets of the second subarea that are occupied using the second query.

In another embodiment, inputting the at least one navigation query and the plurality of key-value pairs into the CAT includes converting the at least one navigation query into a query input using a temporal self-attention transformer.

In another embodiment, updating the model based on the set of weighted sums includes deriving, from the set of weighted sums a set of depth estimates corresponding to the 3D environment; and deriving, from the set of depth estimates, a depth map for the 3D environment.

Additional embodiments and features are set forth in part in the description that follows, and in part will become apparent to those skilled in the art upon examination of the specification or may be learned by the practice of the invention. A further understanding of the nature and advantages of the present invention may be realized by reference to the remaining portions of the specification and the drawings, which forms a part of this disclosure.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The description and claims will be more fully understood with reference to the following figures and data graphs, which are presented as exemplary embodiments of the invention and should not be construed as a complete recitation of the scope of the invention.

FIG. 1A is a conceptual diagram of an autonomous mobile robot implementing systems configured in accordance with some embodiments of the invention.

FIGS. 1B-1D illustrate an autonomous mobile robot operating in accordance with particular embodiments of the invention.

FIGS. 2A-2D illustrates sensory mechanisms, and images obtained thereof, configured in accordance with a number of embodiments of the invention.

FIGS. 3A-3G illustrates images obtained using a depth algorithm applied in accordance with several embodiments of the invention.

FIG. 4 conceptually illustrates a multi-sensor calibration setup in accordance multiple embodiments of the invention.

FIG. 5 is a conceptual diagram of an end-to-end trainable architecture utilized by systems configured in accordance with many embodiments of the invention.

FIG. 6 is a conceptual diagram of a neural network architecture, operating on a stream of multi-camera inputs received in accordance with numerous embodiments of the invention.

FIG. 7 is a conceptual diagram of a transformer architecture in accordance with numerous embodiments of the invention.

FIGS. 8-9 illustrate neural network architecture applied to developing long-horizon planning and runtime optimization for vehicles configured in accordance with a number of embodiments of the invention.

FIGS. 10-11 conceptually illustrate sim-to-real transfers performed in accordance with some embodiments of the invention.

### DETAILED DESCRIPTION

Autonomous navigation systems, autonomous mobile robots, sensor systems, and neural network architectures that can be utilized in machine vision and autonomous navigation applications in accordance with many embodiments of the invention, are described herein. Systems and methods may be directed to but are not limited to delivery robot implementation. Autonomous vehicle functionality may include, but is not limited to architectures for the development of vehicle guidance, polarization and calibration configurations in relation to sensory instruments, and transfers of simulated knowledge of environments to real-world applied knowledge (sim-to-real).

Autonomous vehicles operating in accordance with many embodiments of the invention may utilize neural network architectures that can utilize inputs from one or more sensory instruments (e.g., cameras). Attention within the neural networks may be guided by utilizing queries corresponding to particular inferences attempted by the network. Outputs by perception neural networks can be driven by and provide outputs to a planner. In several embodiments, the planner can perform high-level planning to account for intended system responses and/or other dynamic agents. Planning may be influenced by network attention, sensory input, and/or neural network learning.

As is discussed in detail below, a variety of machine learning models can be utilized in an end-to-end autonomous navigation system. In several embodiments, individual machine learning models can be trained and then incorporated within the autonomous navigation system and utilized when performing end-to-end training of the overall autonomous navigation system.

In several embodiments, perception models take inputs from a sensor platform and utilize the concept of attention to identify the information that is most relevant to a planner process within the autonomous navigation system. The perception model can use attention transformers that receive any of a variety of inputs including information provided by the planner. In this way, the specific sensor information that is highlighted using the attention transformers can be driven by the state of the planner.

In accordance with numerous embodiments, end-to-end training may be performed using reinforcement and/or self-supervised representation learning. The term reinforcement learning typically refers to machine learning processes that optimize the actions taken by an “intelligent” entity within an environment (e.g., an autonomous vehicle). In continual reinforcement learning, the entity is expected to optimize future actions continuously while retaining information on past actions. In a number of embodiments, world models are utilized to perform continual reinforcement learning. World models can be considered to be abstract representations of external environments surrounding the autonomous vehicle that contains the sensors that perceive that environment. In several embodiments, world models provide simulated environments that enable the control processes utilized to control an autonomous vehicle to learn information about the real world, such as configurations of the surrounding area. Under continuous reinforcement learning, certain embodiments of the invention utilize attention mechanisms to amplify or decrease network focus on particular pieces of data, thereby mimicking behavioral/cognitive attention. In many embodiments, world models are continuously updated by a combination of sensory data and machine learning performed by associated neural networks. When sufficient detail has been obtained to complete the current actions, world models function as a substitute for the real environment (sim-to-real transfers).

In a number of embodiments, the machine learning models used within an autonomous navigation system can be improved by using simulation environments. Simulating data at the resolution and/or accuracy of the sensor employed on an autonomous mobile robot implemented in accordance with various embodiments of the invention is compute-intensive, which can make end-to-end training challenging. Rather than having to simulate data at the sensory level, processes for performing end-to-end training of autonomous navigation systems in accordance with various embodiments of the invention are able to use lower computational power by instead using machine learning to develop “priors” that capture aspects of the real world accurately represented in simulation environments. World models may thereby remain fixed and the priors used to translate inputs from simulation or from the real world into the same latent space.

As can readily be appreciated, autonomous navigation systems in accordance with various embodiments of the invention can utilize sensor platforms incorporating any of a variety of sensors. In various embodiments, sensors including (but not limited to) laser imaging, detection, and ranging (LiDAR) systems and/or camera configurations may be utilized to gather information concerning the environment surrounding an autonomous mobile robot. In a number of embodiments, the self-supervised calibration is performed using feature detection and optimization. In certain embodiments, the sensor(s) are periodically maintained using self-supervised calibration.

Autonomous vehicles, sensor systems that can be utilized in machine vision applications, and methods for controlling autonomous vehicles in accordance with various embodiments of the invention are discussed further below.

### A. Autonomous Navigation System Implementations

Turning now to the drawings, systems and methods for implementing autonomous navigation systems configured in accordance with various embodiments of the invention are illustrated. Such autonomous navigation systems may enhance the accuracy of navigation techniques for autonomous driving and/or autonomous mobile robots including (but not limited to) wheeled robots. In many embodiments, autonomous mobile robots are autonomous navigation systems capable of self-driving through tele-ops. Autonomous mobile robots may exist in various sizes and/or be applied to a variety of purposes including but not limited to retail, e-commerce, supply, and/or delivery vehicles.

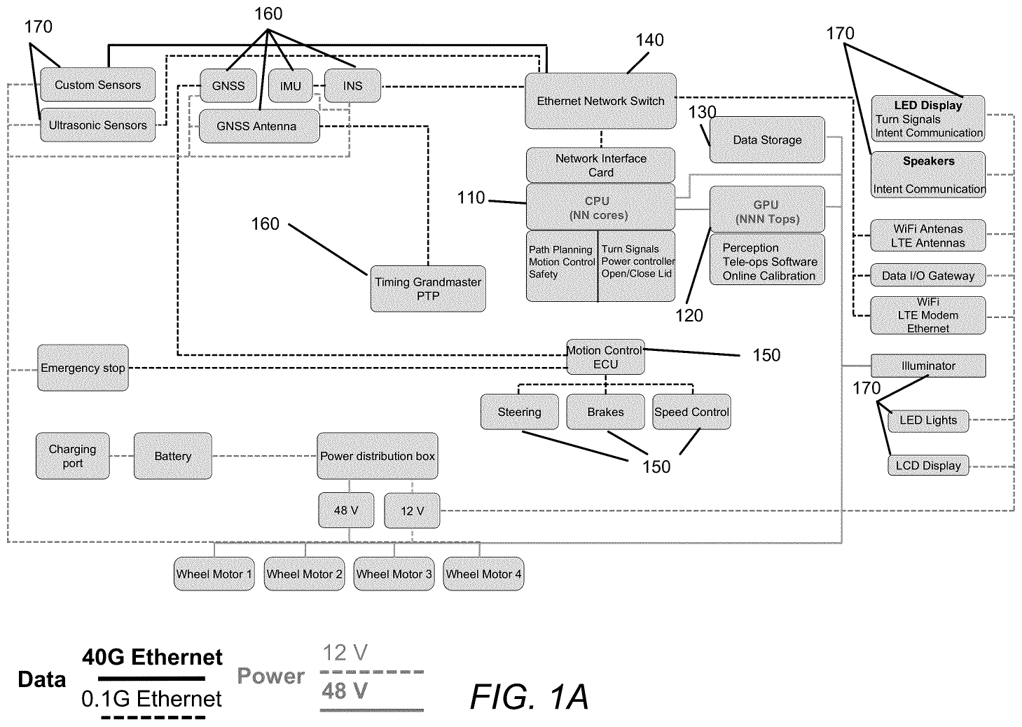

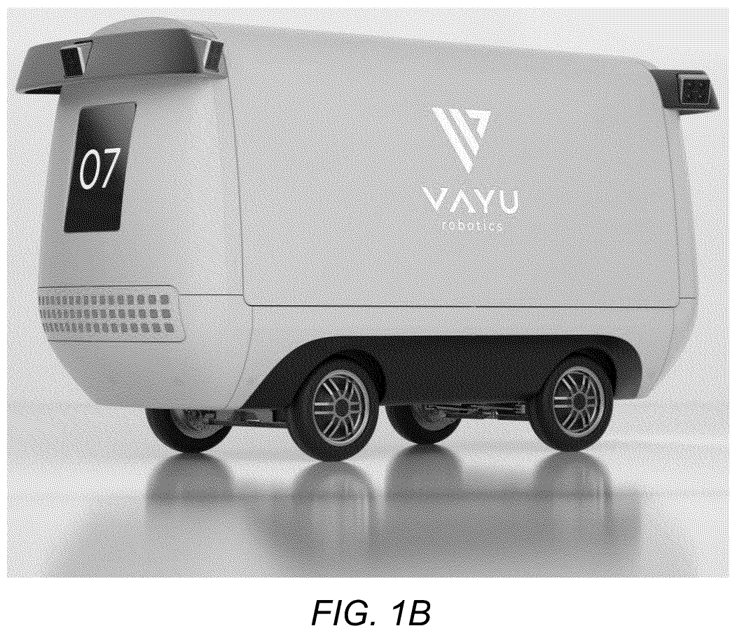

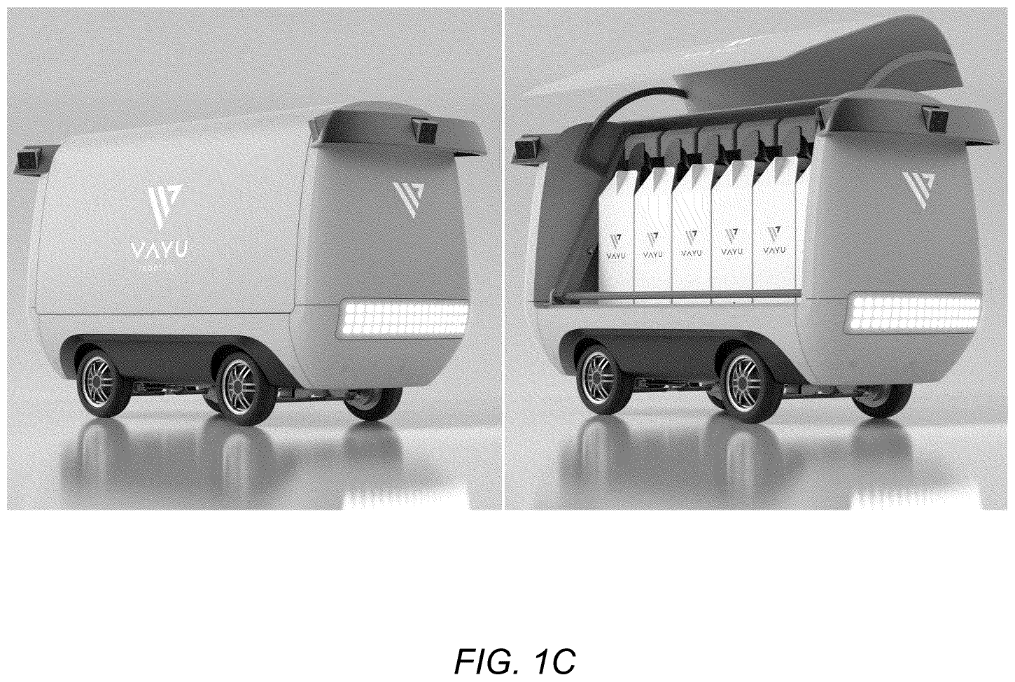

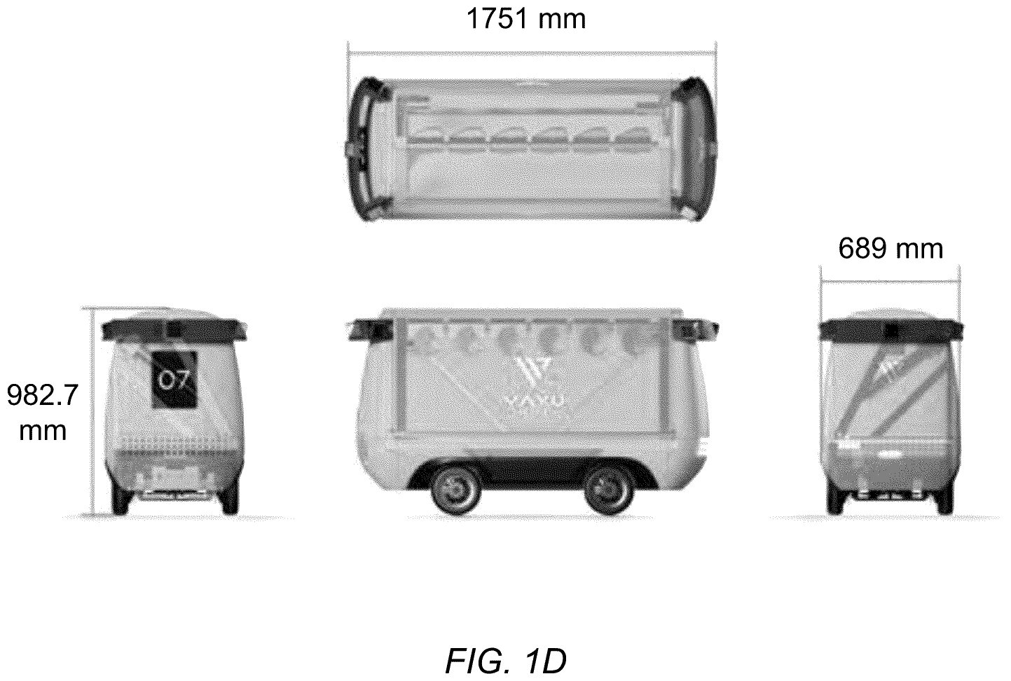

A conceptual diagram of an autonomous mobile robot implementing systems operating in accordance with some embodiments of the invention, is illustrated in FIG. 1A. Robot implementations may include but are not limited to one or more processors, such as a central processing unit (CPU) 110 and/or a graphics processing unit (GPU) 120; a data storage 130 component; one or more network hubs/connecting components (e.g., an ethernet network switch 140), engine control units (ECUs) 150, various navigation instruments 160 and peripherals 170, intent communication 180 components, and a power distribution system 190.

Hardware-based processors 110, 120 may be implemented within autonomous navigation systems and other devices operating in accordance with various embodiments of the invention to execute program instructions and/or software, causing computers to perform various methods and/or tasks, including the techniques described herein. Several functions including but not limited to data processing, data collection, machine learning operations, and simulation generation can be implemented on singular processors, on multiple cores of singular computers, and/or distributed across multiple processors.

Processors may take various forms including but not limited to CPUs 110, digital signal processors (DSP), core processors within Application Specific Integrated Circuits (ASIC), and/or GPUs 120 for the manipulation of computer graphics and image processing. CPUs 110 may be directed to autonomous navigation system operations including (but not limited to) path planning, motion control safety, operation of turn signals, the performance of various intent communication techniques, power maintenance, and/or ongoing control of various hardware components. CPUs 110 may be coupled to at least one network interface hardware component including but not limited to network interface cards (NICs). Additionally or alternatively, network interfaces may take the form of one or more wireless interfaces and/or one or more wired interfaces. Network interfaces may be used to communicate with other devices and/or components as will be described further below. As indicated above, CPUs 110 may, additionally or alternatively, be coupled with one or more GPUs. GPUs may be directed towards, but are not limited to ongoing perception and sensory efforts, calibration, and remote operation (also referred to as “teleoperation” or “tele-ops”).

Processors implemented in accordance with numerous embodiments of the invention may be configured to process input data according to instructions stored in data storage 130 components. Data storage 130 components may include but are not limited to hard disk drives, nonvolatile memory, and/or other non-transient storage devices. Data storage 130 components, including but not limited to memory, can be loaded with software code that is executable by processors to achieve certain functions. Memory may exist in the form of tangible, non-transitory, computer-readable mediums configured to store instructions that are executable by the processor. Data storage 130 components may be further configured to store supplementary information including but not limited to sensory and/or navigation data.

Systems configured in accordance with a number of embodiments may include various additional input-output (I/O) elements, including but not limited to parallel and/or serial ports, USB, Ethernet, and other ports and/or communication interfaces capable of connecting systems to external devices and components. The system illustrated in FIG. 1A includes an ethernet network switch used to connect multiple external devices on system networks, as is elaborated below. Ethernet network switches configured in accordance with several embodiments of the invention may connect devices including but not limited to, computing devices, Wi-Fi access points, Wi-Fi and Long-Term Evolution (LTE) antennae, and servers in Ethernet local area networks (LANs) to maintain ongoing communication. The system illustrated in FIG. 1A utilizes 40 Gigabit and 0.1 Gigabit Ethernet configurations, but systems arranged in accordance with numerous embodiments of the invention may implement any number of communication standards.

Systems configured in accordance with many embodiments of the invention may be powered utilizing a number of hardware components. Systems may be charged by, but are not limited to batteries and/or charging ports. Power may be distributed through systems utilizing mechanisms including but not limited to power distribution boxes. FIG. 1A discloses a distribution of power into the system in the form of simultaneous 12-volt and 48-volt circuits. Nevertheless, power distribution may utilize power arrangements including but not limited to parallel circuits, series circuits, multiple distributed circuits, and/or singular circuits. Additionally or alternatively, circuits may follow voltages including but not limited to those disclosed in FIG. 1A. System driving mechanisms may obtain mobile power through arrangements including but not limited to centralized motors, motors connected to individual wheels, and/or motors connected to any subset of wheels. Additionally or alternatively, while FIG. 1A discloses the use of a four-wheel system, systems configured in accordance with numerous embodiments of the invention may utilize any number and/or arrangement of wheels depending on the needs associated with a given system.

Autonomous vehicles configured in accordance with many embodiments of the invention can incorporate various navigation and motion-directed mechanisms including but not limited to engine control units 150. Engine control units 150 may monitor hardware including but not limited to steering, standard brakes, emergency brakes, and speed control mechanisms. Navigation by systems configured in accordance with numerous embodiments of the invention may be governed by navigation devices 160 including but not limited to inertial measurement units (IMUs), inertial navigation systems (INSs), global navigation satellite systems (GNSS), cameras, time of flight cameras, structured illumination, light detection and ranging systems (LiDARs), laser range finders and/or proximity sensors. IMUs may output specific forces, angular velocities, and/or orientations of the autonomous navigation systems. INSs may output measurements from motion sensors and/or rotation sensors.

Autonomous navigation systems may include one or more peripheral mechanisms (peripherals). Peripherals 170 may include any of a variety of components for capturing data, including but not limited to cameras, speakers, displays, and/or sensors. In a variety of embodiments, peripherals can be used to gather inputs and/or provide outputs. Autonomous navigation systems can utilize network interfaces to transmit and receive data over networks based on the instructions performed by processors. Peripherals 170 and/or network interfaces in accordance with many embodiments of the invention can be used to gather inputs that can be used to localize and/or navigate ANSs. Sensors may include but are not limited to ultrasonic sensors, motion sensors, light sensors, infrared sensors, and/or custom sensors. Displays may include but are not limited to illuminators, LED lights, LCD lights, LED displays, and/or LCD displays. Intent communicators may be governed by a number of devices and/or components directed to informing third parties of autonomous navigation system motion, including but not limited to turn signals and/or speakers.

An autonomous mobile robot, operating in accordance with various embodiments of the invention, is illustrated in FIGS. 1B-1D. In accordance with some embodiments, autonomous mobile robots may be configured to drive on, but are not limited to public streets, highways, bike lanes, off-road areas, and/or sidewalks. The driving of autonomous mobile robots may be facilitated by models trained using machine learning techniques and/or via teleoperation in real-time. In accordance with many embodiments, system operations may be encoded into the AMR as coordinates within a two-dimensional ( [symbol] ²) reference frame. In this reference frame, navigation waypoints can be represented as destinations an autonomous mobile robot is configured to reach, encoded as XY coordinates in the reference frame ( [symbol] ²). Specific machine learning models that can be utilized by autonomous navigation systems and autonomous mobile robots in accordance with various embodiments of the invention are discussed further below.

While specific autonomous mobile robot and autonomous navigation systems are described above with reference to FIGS. 1A-1D, any of a variety of autonomous mobile robot and/or autonomous navigation systems can be implemented as appropriate to the requirements of specific applications in accordance with various embodiments of the invention. Furthermore, applications and methods in accordance with various embodiments of the invention are not limited to use within any specific autonomous navigation systems or within autonomous navigation systems. Accordingly, it should be appreciated that the system configuration described herein can also be implemented outside the context of an autonomous mobile robot described above with reference to FIGS. 1A-1D. Many systems and methods for implementing autonomous navigation systems and applications in accordance with numerous embodiments of the invention are discussed further below.

As noted above, autonomous mobile robot and autonomous navigation systems in accordance with many embodiments of the invention utilize machine learning models in order to perform functions associated with autonomous navigation. In many instances, the machine learning models utilize inputs from sensor systems. In a number of embodiments, the autonomous navigation systems utilize specialized sensors designed to provide specific information relevant to the autonomous navigation systems including (but not limited to) images that contain depth cues. Various sensors and sensor systems that can be utilized by autonomous navigation systems and the manner in which sensor data can be utilized by machine learning models within such systems in accordance with certain embodiments of the invention and are discussed below.

### B. Sensor Systems

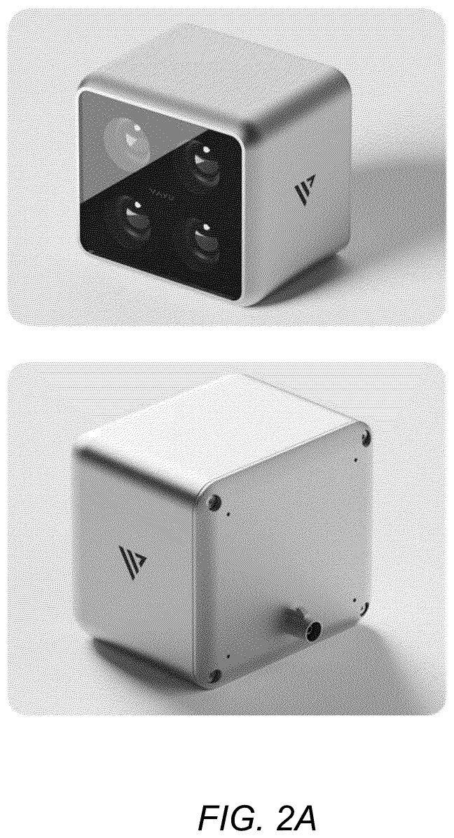

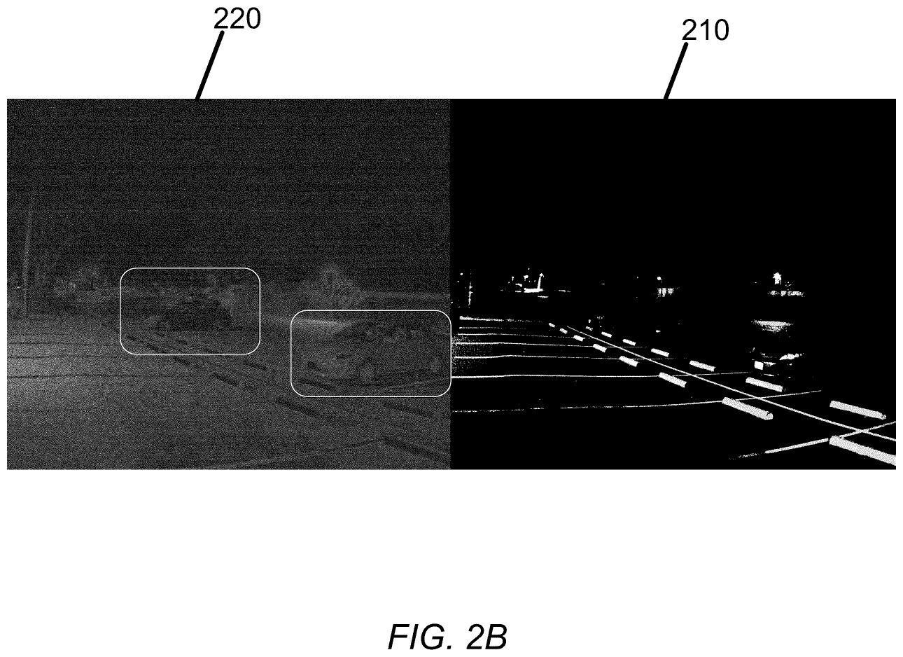

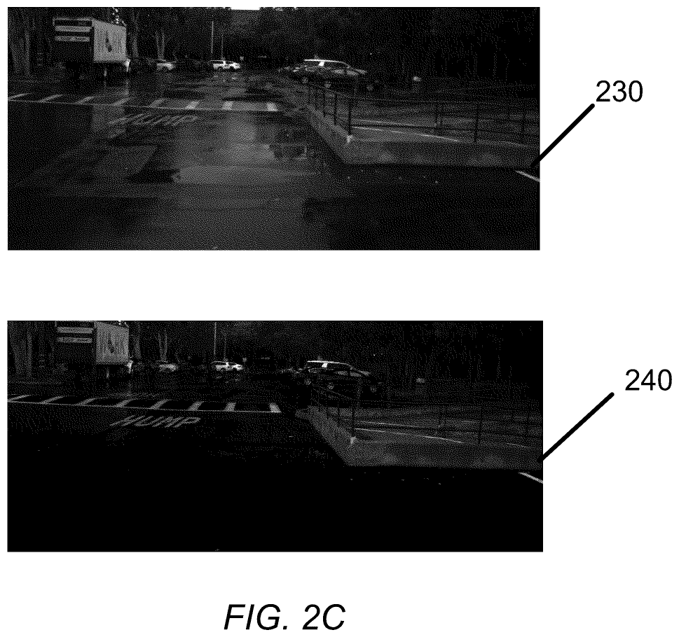

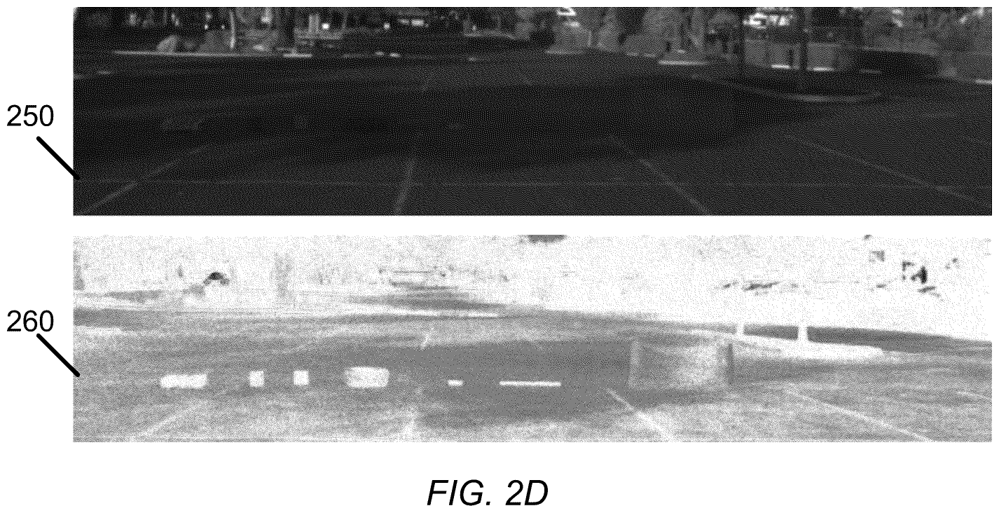

An example of an (imaging) sensor, operating in accordance with multiple embodiments of the invention, is illustrated in FIG. 2A. A variety of sensor systems can be utilized within machine vision applications including (but not limited to) autonomous navigation systems such as (but not limited to) the various autonomous navigation systems and autonomous mobile robots described here. Depth information, which is a term typically used to refer to information regarding the distance of a point or object, can be critically important in many machine vision applications. In many embodiments, a sensor system utilizing one or more of cameras, time of flight cameras, structured illumination, light detection and ranging systems (LiDARs), laser range finders and/or proximity sensors can be utilized to acquire depth information. In many embodiments, multiple cameras are utilized to perform depth sensing by measuring parallax observable when images of the same scene are captured from different viewpoints/perspectives. In certain embodiments, cameras that include polarized filters can be utilized that enable the capture of polarization depth cues. As can readily be appreciated the specific sensors that are utilized within a sensor system depend upon the requirements of a given machine vision application. Processes for acquiring depth information, and calibrating sensor systems and polarized light imaging systems in accordance with various embodiments of the invention are discussed in detail below.

### 1. Polarization Imaging Sensors

Machine vision systems including (but not limited to) machine vision systems utilized within autonomous navigation systems in accordance with various embodiments of the invention can utilize any of a variety of depth sensors. In several embodiments, a depth sensor is utilized that is capable of imaging polarization depth cues. In several embodiments, multiple cameras configured with different polarization filters are utilized in a multi-aperture array to capture images of a scene at different polarization angles. Capturing images with different polarization information can enable the imaging system to generate precise depth maps using polarization cues. Examples of such a camera include the polarization imaging camera arrays produced by Akasha Imaging, LLC and described in Kalra, A., Taamazyan, V., Rao, S. K., Venkataraman, K., Raskar, R. and Kadambi, A., 2020. Deep polarization cues for transparent object segmentation. In Proceedings of the IEEE/CVF Conference on Computer Vision and Pattern Recognition (pp. 8602-8611) the disclosure of which is incorporated by reference herein in its entirety. In addition to or as an alternative, a polarization imaging system that can capture multiple images of a scene at different polarization angles in a single shot using a single aperture can be utilized to capture polarization information (see discussion below).

The benefits of using polarization imaging in autonomous vehicle navigation applications are not limited to the ability to generate high quality depth maps as is evident in FIGS. 2B-2D. Polarization information can be helpful in machine vision applications for detecting the presence of transparent objects, avoiding confusions resulting from reflections, and in analyzing high dynamic range scenes. Referring first to FIGS. 2B and 2C, the first image 230 shows the challenges that can be presented in machine vision applications by reflective surfaces such as wet roads. The second image 240 demonstrates the way in which imaging using polarization filters enables the elimination of reflections in the resulting images. Referring now to FIG. 2D the challenges of interpreting an image 250 of a high dynamic scene containing objects that are in shadow can be appreciated. The image 260 generated using a polarization imaging system shows how clearly objects can be discerned in high dynamic range images using polarization information.

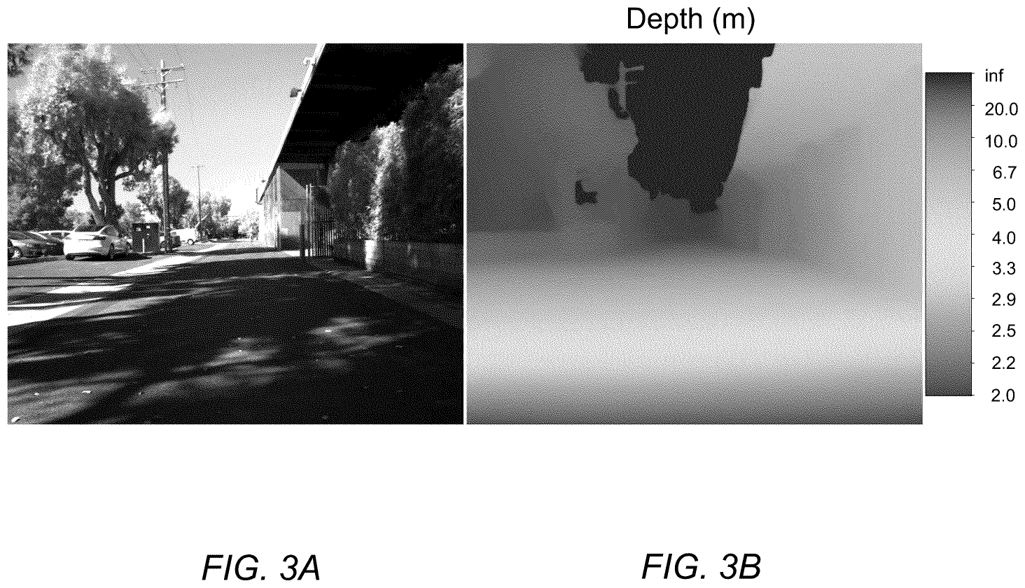

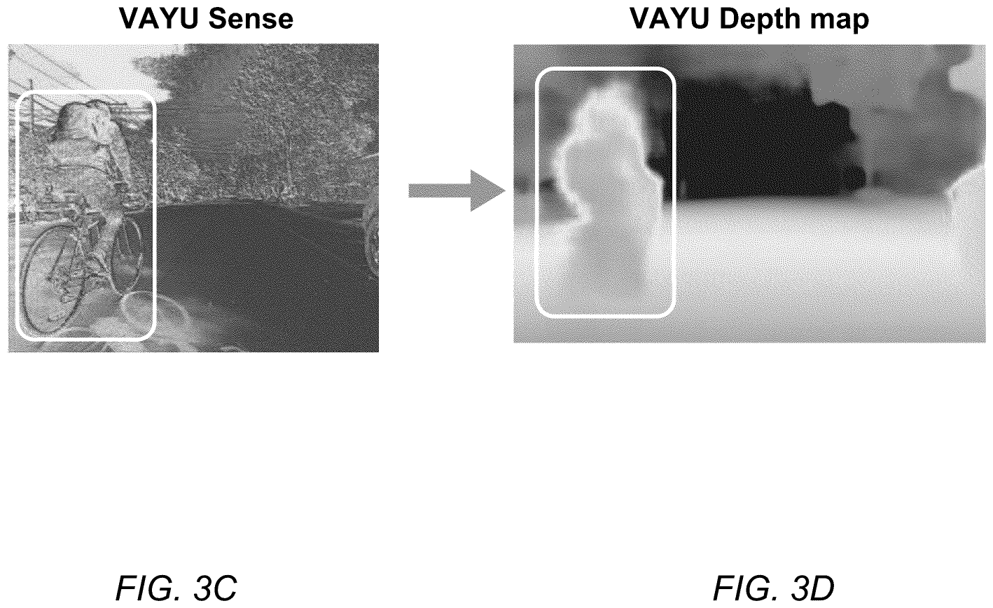

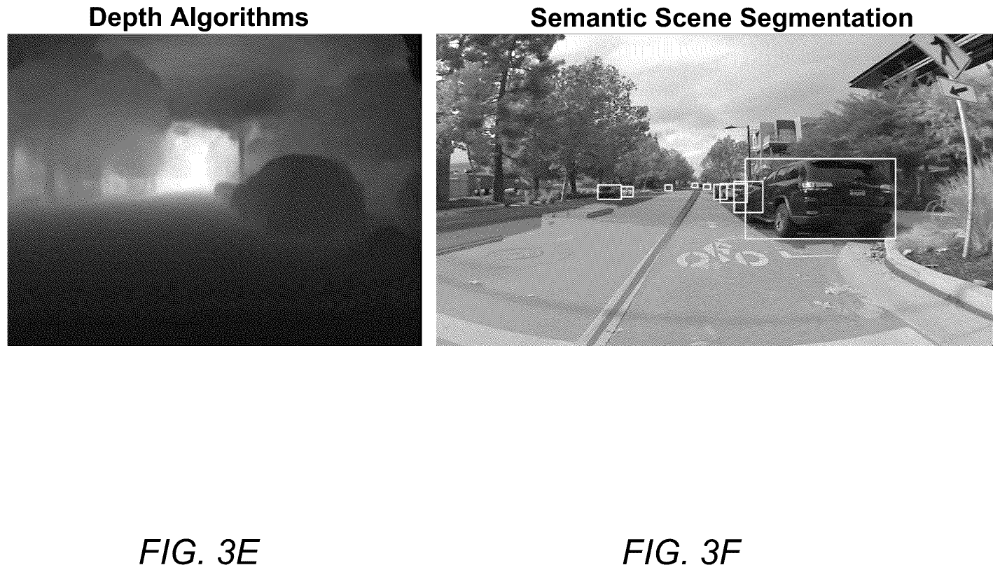

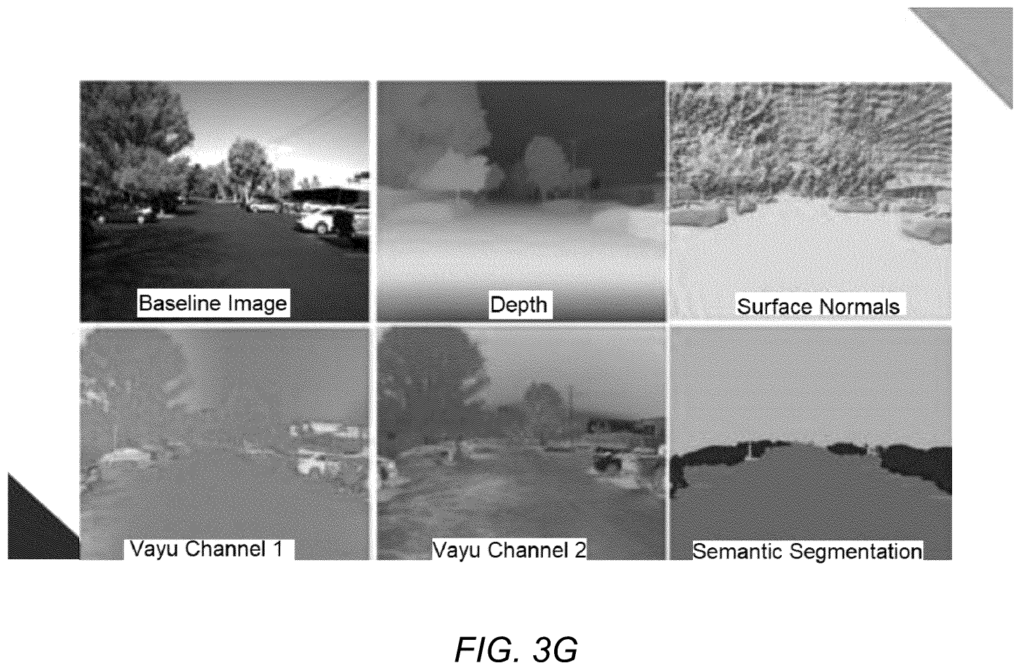

The benefits of using polarization imaging systems in the generation of depth maps can be readily appreciated with reference to FIGS. 3A-3G. FIGS. 3A and 3B show an image of a scene and a corresponding depth map generated using a polarization imaging system similar to the polarization imaging systems described herein. FIGS. 3C and 3D show how polarization information can be utilized to generate high resolution depth maps that can then be utilized to perform segmentation and/or semantic analysis. FIGS. 3E and 3F similarly illustrate how polarization information can be utilized to generate high resolution depth maps that can then be utilized to perform segmentation and/or semantic analysis. FIG. 3G shows a collection of the various representations that can be produced in accordance with multiple embodiments of the invention. For example, potential representations generated by systems configured in accordance with certain embodiments of the invention may include but are not limited to depth maps, surface normal maps, channel-based representations of digital images (e.g., RGB depictions), segmentation analysis maps, and/or semantic analysis maps.

In accordance with many embodiments, depth maps may be utilized to perform segmentation and/or semantic analysis. For example, depth maps may provide new channels of information (i.e., “depth channels”), which may be used in combination with standard channels. Standard channels may include, but are not limited to red, green, and blue color channels. Depth channels may reflect the inferred depth of given pixels relative to the ANS. As such, in accordance with some embodiments, each pixel of an input RGB image may have four channels, including inferred pixel depth. Pixel depth may be used in segmentation and/or semantic analysis in scenarios including but not limiting to determinations of whether particular pixels in three-dimensional space are occupied and extrapolating such determinations to use in collision avoidance and/or planning algorithms.

While specific examples of the benefits of utilizing polarization imaging systems are described herein with reference to FIGS. 2A-3G, sensor platforms in accordance with embodiments of the invention should be understood as not being limited to the use of any specific polarization imaging system and/or need to not incorporate a polarization imaging system at all. Indeed, many autonomous navigation systems in accordance with various embodiments of the invention utilize sensor platforms incorporating conventional cameras. Processes that can be utilized to calibrate the various sensors incorporated within a sensor platform in accordance with an embodiment of the invention are discussed further below.

### 2. Sensor Calibration

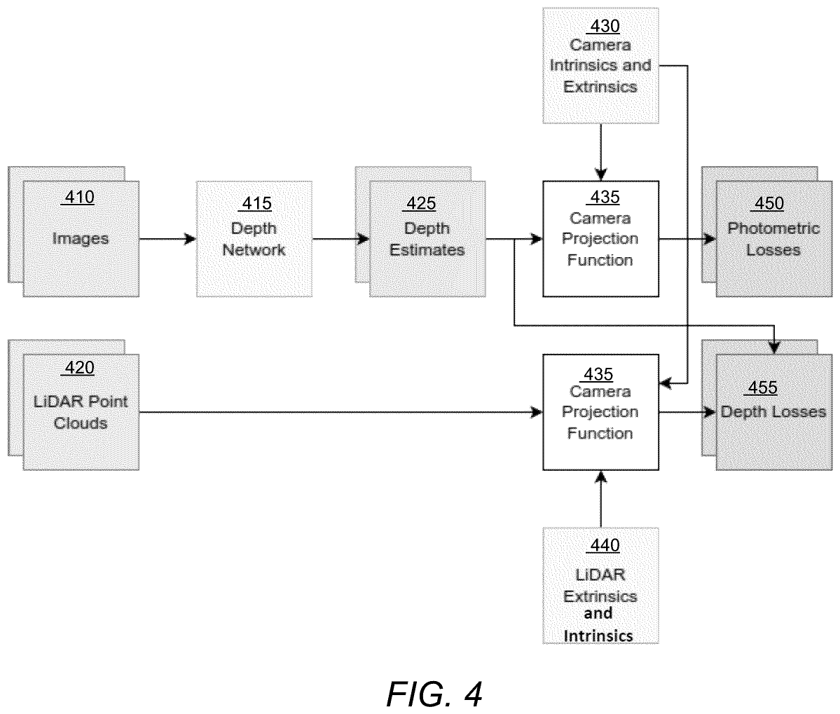

A multi-sensor calibration setup in accordance with multiple embodiments of the invention is illustrated in FIG. 4. Sensor platforms utilized within machine vision systems typically require precise calibration in order to generate reliable information including (but not limited to) depth information. In many applications, it can be crucial to characterize the internal and external characteristics of the sensor suite in use. The internal characteristics of the sensors are typically called intrinsics and the external characteristics of the sensors are called extrinsics. Autonomous mobile robots are an example of a class of autonomous navigation systems that are subject to mechanical forces (e.g. vibration) that can cause sensor platforms to lose calibration over time. Machine vision systems and image processing methods in accordance with various embodiments of the invention enable calibration of the internal (intrinsic) and external (extrinsic) characteristics of sensors including (but not limited to) cameras 430 and/or LiDAR systems 440. In accordance with many embodiments of the invention, cameras may produce images 410 of an area surrounding the autonomous mobile robot. Additionally or alternatively, LiDAR mechanisms may produce LiDAR point clouds 420 identifying occupied points in three-dimensional space surrounding the autonomous mobile robot. Utilizing both the images 410 and the LiDAR point clouds 420, the depth/distance of particular points may be identified by camera projection functions 435. In several embodiments, a neural network 415 that uses images and point clouds of natural scenes as input and produces depth information for pixels in one or more of the input images is utilized to perform self-calibration of cameras and LiDAR mechanisms. In accordance with several embodiments, the neural network 415 is a deep neural network such as (but not limited to) a convolutional neural network that is trained using an appropriate supervised learning technique in which the intrinsics and extrinsics of the sensors and the weight of the deep neural network are estimated so that the depth estimates 425 produced from the neural network 415 are consistent with the captured images and/or the depth information contained within the corresponding LiDAR point clouds of the scene.

Calibration processes may implement sets of self-supervised constraints including but not limited to photometric 450 and depth 455 losses. In accordance with certain embodiments, photometric losses 450 are determined based upon observed differences between the images reprojected into the same viewpoint using features such as (but not limited to) intensity. Depth losses 455 can be determined based upon a comparison between the depth information generated by the neural network 415 and the depth information captured by the LiDAR reprojected into the corresponding viewpoint of the depth information generated by the neural network 415. While self-supervised constraints involving photometric and depth losses are described above, any of a variety of self-supervised constraints can be utilized in the training of a neural network as appropriate to the requirements of specific applications in accordance with various embodiments of the invention.

In several embodiments, the implemented self-supervised constraints may account for known sensor intrinsics and extrinsics 430, 440 in order to estimate the unknown values, derive weights for the depth network 415, and/or provide depth estimates 425 for the pixels in the input images 410. In accordance with many embodiments, the parameters of the depth neural network and the intrinsics and extrinsics of the cameras and LiDAR extrinsics may be derived through stochastic optimization processes including but not limited to Stochastic Gradient Descent and/or an adaptive optimizer such as (but not limited to) the AdamW optimizer implemented within the machine vision system (e.g. within an autonomous mobile robot) or utilizing a remote processing system (e.g. a cloud service). Setting reasonable weights for the neural network 415 may enable the convergence of sensor intrinsic and extrinsic 430, 440 unknowns to satisfactory values. In accordance with numerous embodiments, reasonable weight values may be determined through threshold values for accuracy.

Photometric loss may use known camera intrinsics and extrinsics 430, depth estimates 425, and/or input images 410 to constrain and discover appropriate values for intrinsic and extrinsic 430 unknowns associated with the cameras. Additionally or alternatively, depth loss can use the LiDAR point clouds 420 and depth estimates 425 to constrain LiDAR intrinsics and extrinsics 440. In doing so, depth loss may further constrain the appropriate values for intrinsic and extrinsic 430 unknowns associated with the cameras. As indicated above, optimization may occur when depth estimates 425 from the depth network 415 match the depth estimates from camera projection functions 435. In accordance with a few embodiments, the photometric loss may additionally or alternatively constrain LiDAR intrinsics and extrinsics to allow for their unknowns to be estimated.

While specific processes for calibrating cameras and LiDAR systems within sensor platforms are described above, any of a variety of online and/or offline calibration processes can be utilized as appropriate to the requirements of specific applications in accordance with various embodiments of the invention. Furthermore, autonomous navigation systems in accordance with many embodiments of the invention can utilize a variety of sensors including cameras that capture depth cues from polarized light.

### C. Trainable Architectures

In accordance with numerous embodiments of the invention, one or more machine learning methods may be used to train machine learning models used to perform autonomous navigation. In accordance with certain embodiments of the invention, autonomous system operation may be guided based on one or more neural network architectures that operate on streams of multi-sensor inputs. Such architectures may apply representation learning and/or attention mechanisms in order to develop continuously updating manifestations of the environment surrounding an autonomous mobile robot (also referred to as “ego vehicle” and “agent” in this disclosure). Within systems operating in accordance with numerous embodiments, for example, one or more cameras can provide input images at each time step t, where each image has a height H and a width W, and a number of channels C (i.e. each image is [symbol] ). Observations obtained from sensors (e.g., cameras, LiDAR, etc.) may be provided as inputs to neural networks, such as (but not limited to) convolutional neural networks (CNNs), to determine system attention. Neural network architectures, including but not limited to CNNs, may take various forms as elaborated on below.

### 1. End-to-end Trainable Architecture

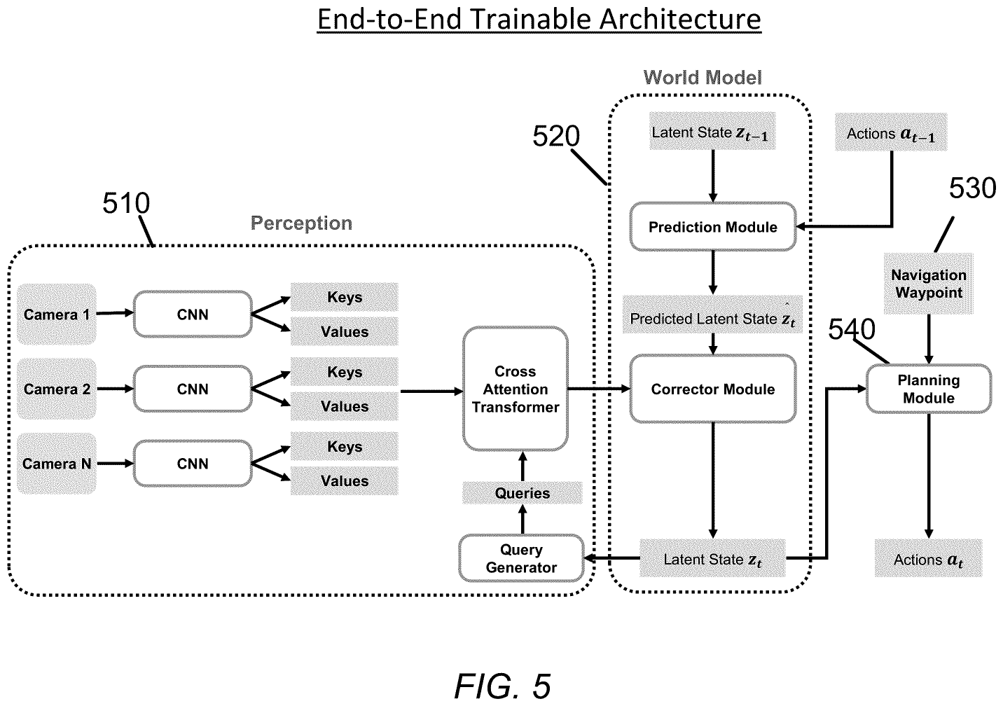

An example of an end-to-end trainable architecture utilized by systems configured in accordance with multiple embodiments of the invention is illustrated in FIG. 5. Trainable architectures may depend on factors including but not limited to ongoing system perception 510 and world models 520 that encode the systems' present understanding of their environments and/or external conditions.

In accordance with several embodiments of the invention, the generation of world models 520 may be based on machine learning techniques including but not limited to model-based reinforcement learning and/or self-supervised representation learning. Additionally or alternatively, perception architectures 510 may input observations obtained from sensors (e.g., cameras) into CNNs to determine system attention. In accordance with numerous embodiments, the information input into the CNN may take the form of an image of shape (H, W, C), where H=height, W=width, and C=channel depth.

As disclosed above, system attention may be guided by ongoing observation data. Perception architectures 510 of systems engaging in autonomous driving attempts may obtain input data from a set of sensors associated with a given autonomous mobile robot (i.e., the ego vehicle). For example, as disclosed in FIG. 5, N cameras mounted to an autonomously mobile robot can each input obtained images into a perception architecture 510. The perception architecture assists the autonomous navigation system to identify image data that is relevant to the autonomous navigation task. In accordance with some embodiments, each sensor may correspond to its own neural network (e.g. a CNN). Additionally or alternatively, the output of the CNN can take the form of a representation of features of the input data and also take a given shape (e.g., (H′, W′, C′)). The outputs of the neural network can be concatenated with position embeddings derived from the intrinsic and extrinsic camera calibration and the location of a patch (e.g., a subsection of the image input into the CNN) to generate keys and values that are utilized in subsequent processing including (but not limited to) the various cross attention processes described below. Alternatively or additionally, multiple sensors may input sensory information into a single CNN to obtain key-value pairs with respect to the sensor information provided by each sensor. In accordance with a number of embodiments of the invention, each key-value pair (kᵢ, vᵢ) corresponds to one of the sensors (e.g., camera i of the N cameras). Additionally or alternatively, each key-value pair may correspond to particular sub-images/collections of pixels captured by one or more sensors and/or particular “landmarks” captured in particular sub-images/collections of pixels.

Autonomous navigation systems can use the key-value pairs to determine system attention by removing irrelevant attributes of the observations and retaining the task-relevant data. Task relevance may be dependent on but is not limited to query input from at least one (e.g., navigation-directed) query. Attention mechanisms may depend on mapping the query and the groups of key-value pairs to weighted sums, representative of the weight (i.e., attention) associated with particular sensory data (e.g., specific images). In a number of embodiments, the mapping is performed by a Cross-Attention Transformer (CAT) and is guided by the query input. The CAT may compute the weighted sums, assigned to each value (vᵢ), by assessing the compatibility between a retrieved query (q) and the key (kᵢ) corresponding to the value. Transformer techniques are described in Vaswani et al., Attention Is All You Need, 31st Conference on Neural Information Processing Systems (NIPS 2017), Long Beach, CA, the content of which including the disclosure related to cross-attention transformer process is hereby incorporated herein by reference in its entirety.

In accordance with certain embodiments of the invention, weighted sums determined by CATs may be used to update world models 520. In some embodiments, world models 520 may incorporate latent state estimates that can summarize and/or simplify observed data for the purpose of training world models 520. As such, a latent state at time t (zₜ) may refer to a representation of the present state of the environment surrounding the autonomous mobile robot. Additionally or alternatively, a latent state at time t−1 (zₜ₋₁) may refer to the last estimated state of the environment. Predictions of the new state of the environment (zₜ) may be based in part on the latent state at time t−1 (zₜ₋₁), including but not limited to the predicted movement of dynamic entities in the surrounding environment at time t−1. Additionally or alternatively, the past actions of the autonomous mobile robot may be used to estimate predicted latent states. Predictions may be determined by specific components and/or devices including but not limited to a prediction module implemented in hardware, software and/or firmware using a processor system. When a prediction has been made based on the last estimated state of the environment (zₜ₋₁), systems may correct the prediction based on the weighted sums determined by the CAT, thereby including the “presently observed” data. These corrections may be determined by specific components and/or devices including but not limited to a correction module. The corrected/updated prediction may then be classified as the current latent state (zₜ).

In accordance with a number of embodiments of the invention, query inputs may be generated from the current latent state (zₜ). Queries may function as representations of what systems are configured to infer from the environment, based on the most recent estimated state(s) of the environment. Query inputs may specifically be derived from query generators in the systems. Various classifications of queries are elaborated upon below.

In addition to knowledge of the surrounding system (e.g., world models), latent states may be used by systems to determine their next actions (aₜ). For example, when a latent state reflects that a truck is on a collision course with an autonomous mobile robot, a system may respond by having the autonomous mobile robot, sound an audio alert, trigger a visual alert, brake and/or swerve, depending on factors including but not limited to congestion, road traction, and present velocity. Actions may be determined by one or more planning modules 540 configured to optimize the behavior of the autonomous mobile robot for road safety and/or system efficiency. The one or more planning modules 540 may, additionally or alternatively, be guided by navigation waypoints 530 indicative of the intended long-term destination of the autonomous mobile robot. The planning modules 540 can be implemented in hardware, software and/or firmware using a processor system that is configured to provide one or more neural networks that output system actions (aₜ) and/or optimization procedures. Autonomous navigation systems may utilize the aforementioned attention networks to reduce the complexity of content that real time planning modules 540 are exposed to and/or reduce the amount of computing power required for the system to operate.

### 2. Planner-Guided Perception Architectures

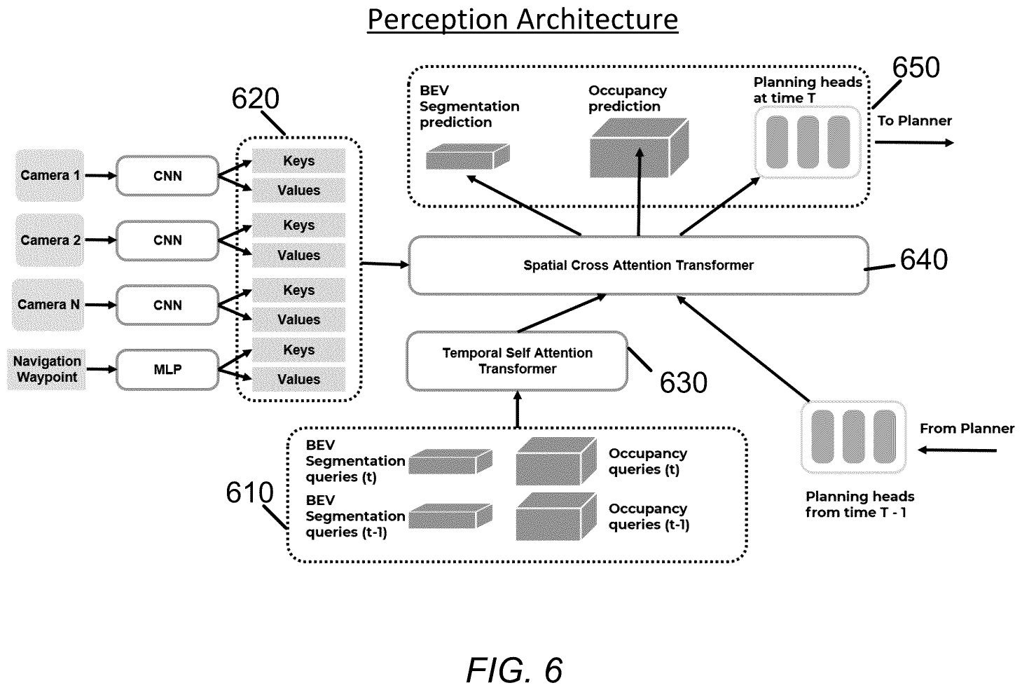

An example of a planner-guided perception architecture utilized by autonomous navigation systems in accordance with numerous embodiments of the invention is illustrated in FIG. 6. Planners may refer to mechanisms, including but not limited to planning modules 540, that can be utilized by autonomous navigation systems to plan motion. Autonomous mobile robot motion can include, but is not limited to, high-level system responses, long-horizon driving plans and/or on-the-spot system actions. For planner-guided perception architectures, it is possible for the autonomous navigation system to direct attention in a dynamic way that is guided by the planner so that the autonomous navigation system can pay attention to the scene elements that are relevant in real-time to the time varying goals and/or actions of the planner.

Planner-guided perception architectures in accordance with many embodiments of the invention are capable of supporting different types of queries for the transformer mechanism. Queries can be considered to be a representation of what an autonomous navigation system is seeking to infer about the world. For example, an autonomous navigation system may want to know the semantic labels of a 2-dimensional grid space around ego in the Bird's Eye View. Each 2-D voxel in this grid can have one or many classes associated with it, such as a vehicle or drivable road.

As noted above, different types of queries can be provided to a cross-attention transformer in accordance with various embodiments of the invention. In a number of embodiments, queries 610 provided to a cross-attention transformer within planner-guided perception architectures may be defined statically and/or dynamically. Static queries may include pre-determined representations of information that autonomous navigation systems intend to infer about the surrounding environment. Example static queries may include (but are not limited to) Bird's Eye View (BEV) semantic queries and 3D Occupancy queries. 3D Occupancy queries may represent fixed-size three-dimensional grids around autonomous mobile robots. Occupancy grids may be assessed in order to confirm whether voxels in the grids are occupied by one or more entities. Additionally or alternatively, BEV semantic queries may represent fixed-size, two-dimensional grids around autonomous mobile robots. Voxels in the semantic grids may be appointed one or more classes including but not limited to vehicles, pedestrians, buildings, and/or drivable portions of road. Systems may, additionally or alternatively, generate dynamic queries for instances where additional sensory data is limited. Dynamic queries may be generated in real time and/or under a time delay. Dynamic queries may be based on learned perception representation and/or based on top-down feedback coming from planners.

As is the case above, system attention for planner-guided architectures may be guided by ongoing observation data. Observational data may still be obtained from a set of sensors, including but not limited to cameras, associated with the ego vehicle. In accordance with some embodiments, multiple types of neural networks may be utilized to obtain key-value pairs (kᵢ, vᵢ) 620. For instance, each sensor may again correspond to its own CNN, used to generate an individual key-value pair. Additionally or alternatively, key-value pairs may be obtained from navigation waypoints. For example, navigation waypoint coordinates may be input into neural networks including but not limited to Multi-Layer Perceptrons (MLPs), Recurrent Neural Networks (RNNs), and/or CNNs.

In a number of embodiments, multiple different cross-attention transformers can be utilized to perform a cross-attention transformation process. In the illustrated embodiment, a temporal self-attention transformer 630 is utilized to transform BEV segmentation and occupancy queries into an input to a spatial cross-attention transformer 650 that also receives planning heads from a planner. In accordance with many embodiments of the invention, planning heads may refer to representations of queries coming from planners. Planning heads may come in many forms including but not limited to vectors of neural activations (e.g. a 128-dimensional vector of real numbers).

Temporal information can play a crucial role while learning a representation of the world. For example, temporal information is useful in scenes of high occlusion where agents can drop in and out of the image view. Similarly, temporal information is often needed when the network has to learn about the temporal attributes of the scene such as velocities and accelerations of other agents, or understand if obstacles are static or dynamic in nature. A self-attention transformer is a transformer that receives a number of inputs and uses interactions between the inputs to determine where to allocate attention. In several embodiments, the temporal self-attention transformer 630 captures temporal information using a self-attention process. At each timestamp t, the encoded BEVₜ₋₁ features are converted to BEV′ₜ₋₁ using ego motion to adjust to the current ego frame. A self-attention transformer process is then applied between the queries BEVₜ and BEV′ₜ₋₁ to generate attention information that can be utilized by the autonomous navigation system (e.g. as inputs to a spatial cross-attention transformer).

In a number of embodiments, the spatial cross-attention transformer 640 within the planner-guided perception architecture is responsible for learning a transformation from the key-values derived from the image space to a Bird's Eye View representation of the scene centered around an autonomous mobile robot. At each timestep t, the BEV queries are taken from the output of the temporal self-attention transformer 630 and a cross-attention process is performed using these outputs and the key-value generated from the outputs of the sensors within the sensor platform. The resulting outputs can include on or more of BEV segmentation predictions, occupancy predictions and planning heads at time t.

While specific perception architectures are described above with reference to FIG. 6, any of a variety of perception architectures can be utilized including (but not limited to) perception architectures that utilizes queries and inputs from the planner to generate relevant outputs that can be subsequently utilized by the planner to perform autonomous navigation as appropriate to the requirements of specific applications in accordance with various embodiments of the invention. Furthermore, while the planner-driven perception systems described above with reference to FIG. 6 can be utilized within any of the autonomous navigation systems and/or autonomous mobile robots described herein, the planner-driven perception systems can be utilized in any of a variety of autonomous navigation systems and should be understood as not being limited to use within any specific autonomous navigation system architecture.

In several embodiments, the planner-driven perception architecture illustrated in FIG. 6 can be implemented on a Nvidia Jetson Orin processor system. This embedded system-on-chip includes multiple compute elements—two DLAs, a GPU, and a 12-core ARM CPU. In order to maximize resource utilization, the autonomous navigation system deploys the per-camera CNNs on the two DLAs. For an 8-camera setup, 4 images can be processed on each DLA. Since the processing of the images can run in parallel, no communication is needed during forward operation. The output keys and values can be transferred to the GPU memory. In this configuration, the temporal and spatial attention transformers can run on the GPU.

In a number of embodiments, the spatial cross-attention transformer 640 within the planner-guided perception architecture is responsible for learning a transformation from the key-values derived from the image space to a Bird's Eye View representation of the scene centered around an autonomous mobile robot. At each timestep t, the BEV queries are taken from the output of the temporal self-attention transformer 630 and a cross-attention process is performed using these outputs and the key-value generated from the outputs of the sensors within the sensor platform. The resulting outputs can include (but are not limited to) one or more of occupancy predictions, planning heads at time t, and/or BEV segmentation predictions.

In accordance with a number of embodiments of the invention, planning architectures may depend on BEV segmentation predictions that come in various forms, including (but not limited) to BEV semantic segmentation. As suggested above, BEV semantic segmentation may refer to tasks directed toward producing one or more semantic labels at each location in grids centered at the autonomous mobile robot. Example semantic labels may include, but are not limited to, drivable region, lane boundary, vehicle, and/or pedestrian. Systems configured in accordance with some embodiments of the invention may have the capacity to produce BEV semantic segmentation using BEV/depth transformer architectures.

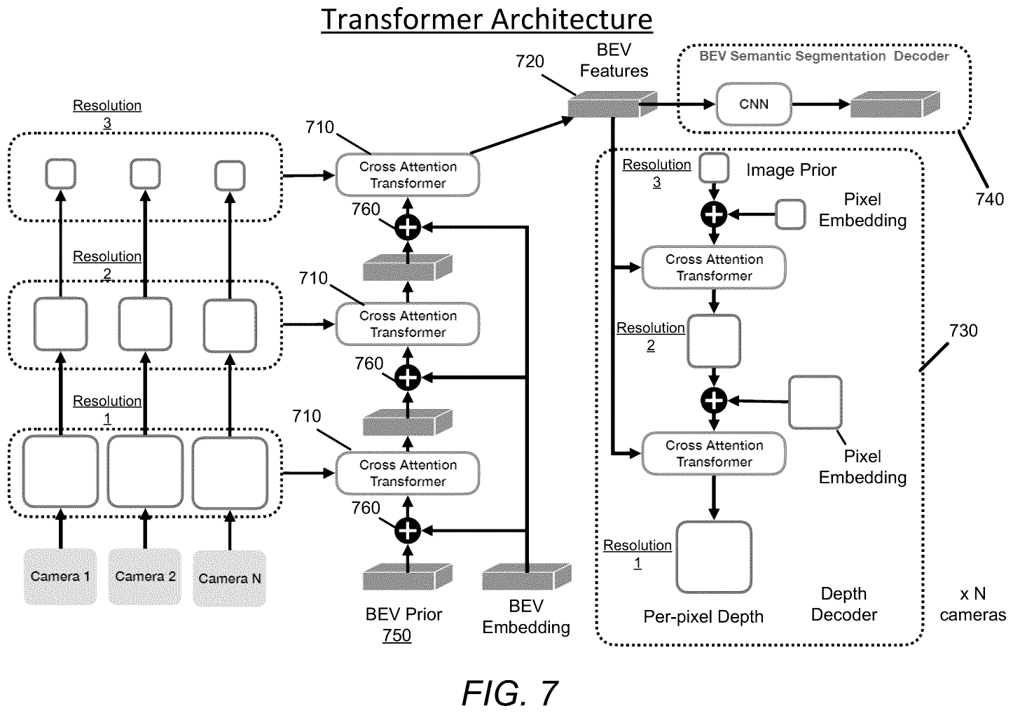

An example of a BEV/depth transformer architecture utilized by autonomous navigation systems in accordance with several embodiments of the invention is illustrated in FIG. 7. BEV/depth transformer architectures may take input images from multi-camera (and/or single-camera) configurations. BEV/depth transformers can be trained using standard variants of stochastic gradient descent and/or standard loss functions for self-supervised depth estimation and/or BEV semantic segmentation.

In an initial encoding step, the transformer architectures may extract BEV features from input images, utilizing one or more shared cross-attention transformer encoders 710 (also referred to as “transformers”). In accordance with a number of embodiments, each shared cross-attention transformer 710 may correspond to a distinct camera view. In accordance with many embodiments of the invention, learned BEV priors 750 may be iteratively refined to extract BEV features 720. Refinement of BEV priors 750 may include, but is not limited to, the use of (current) BEV features 720 taken from the BEV prior(s) 750 to construct queries 760. Constructed queries 760 may be input into cross attention transformers 710 that may cross-attend to features of the input images (image features). In accordance with some embodiments, in configurations where multiple transformers 710 are used, successive image features may be extracted at lower image resolutions. At each resolution, the features from all cameras in a configuration can be used to construct keys and values towards the corresponding cross-attention transformer 710.

In accordance with a number of embodiments of the invention, the majority of the processing performed in such transformer architectures may be focused on the generation of the BEV features 720. BEV features 720 may be produced in the form of, but are not limited to, BEV grids. BEV transformer architectures may direct BEV features 720 to multiple processes, including but not limited to depth estimation and segmentation.

Under the segmentation process, BEV features 720 may be fed into BEV semantic segmentation decoders 740, which may decode the features 720 into BEV semantic segmentation using convolutional neural networks. In accordance with many embodiments of the invention, the output of the convolutional neural networks may be multinomial distributions over a set number (C) semantic categories. Additionally or alternatively, each multinomial distribution may correspond to a given location on the BEV grid(s). Systems configured in accordance with some embodiments may train BEV semantic segmentation decoders 740 on small, labeled supervised datasets.

Additionally or alternatively, BEV features 720 may be fed into depth decoders 730, which may decode the BEV features 720 into per-pixel depth for one or more camera views. In accordance with many embodiments of the invention, depth decoders 730 may decode BEV features 720 using one or more cross attention transformer decoders. Estimating per-pixel depth in camera views can be done using methods including but not limited to self-supervised learning. Self-supervised learning for the estimation of per-pixel depth may incorporate the assessment of photometric losses. Depth decoders 730 can be trained on small labeled supervised datasets which, as disclosed above, can be used to train BEV semantic segmentation decoders 740. Additionally or alternatively, depth decoders 730 can be trained with larger unsupervised datasets.

In accordance with several embodiments, depth decoders 730 may input BEV features 720 and/or output per-pixel depth images. Depth decoders 730 may work through successive refinement of image features, starting with learned image priors. At each refinement step, the image features may be combined with pixel embeddings to produce depth queries. These depth queries may be answered by cross-attending to the input BEV features 720. Additionally or alternatively, the BEV features 720 may be used to construct keys and values, up-sampled, and/or further processed through convolutional neural network layers.

In accordance with some embodiments of the invention, image features used in the above encoding step may be added to the image features refined by depth decoders 730 over one or more steps. In accordance with some embodiments, at each step, the resolution of the set of image features may double. This may be done until the resolution of the image features again matches the input image resolution (i.e., resolution 1). At this stage, the image features may be projected to a single scalar at each location which can encode the reciprocal of depth. The same depth decoder 730 may be used N times to decode the N images in up to N locations, wherein runs can differ in the pixel embeddings for each image.

As can readily be appreciated, any of a variety of processing systems can be utilized to implement a perception processing pipeline to process sensor inputs and produce inputs to a planner as appropriate to the requirements of specific applications in accordance with various embodiments of the invention.

### 3. Neural Planner Architectures

As suggested above, training of a planning process can be greatly enhanced through the use of simulation environments. Simulation environments and machine learning models may be derived from and updated in response to neural network calculations and/or sensory data. Such models, when generated in accordance with numerous embodiments of the invention may represent aspects of the real world including but not limited to the fact that the surrounding area is assessed in three dimensions, that driving is performed on two-dimensional surfaces, and that 3D and 2D space is taken up by objects in the simulation (e.g., pedestrians, cars), parts of space can be occluded, and collisions occur if two objects try to occupy the same space at the same time. However, simulating data at the sensor-level accurately is compute-intensive, which means simulation environments are often not accurate at the sensor-level. This makes training closed-loop machine learning models challenging. Process for performing end-to-end training of autonomous navigation systems in accordance with various embodiments of the invention address this problem by learning a strong high-level prior in simulation. The prior captures aspects of the real-world that are accurately represented in simulation environments. The prior is then imposed in a top-down way on the real-world sensor observations. In several embodiments, this is done using run-time optimization with an energy function that measures compatibility between the observation and the latent state of the agent. A safe operation threshold is calibrated using the value of the objective function that is reached at the end of optimization. Various processes that can be utilized to optimize autonomous navigation systems in accordance with certain embodiments of the invention are discussed further below.

### (a) Long Horizon and High-Level Planner Architectures

Autonomous navigation systems in accordance with a number of embodiments of the invention separate planning mechanisms according to intended levels of operation. Prospective levels may include but are not limited to high-level planning and low-level planning. In accordance with various embodiments of the invention, complex strategies determined at a large scale, also known as high-level planning, can operate as the basis for system guidance and/or consistent system strategies (e.g., predictions of common scenarios for autonomous mobile robots). Additionally or alternatively, low-level planning may refer to immediate system responses to sensory input (i.e., on-the-spot decision-making).

High-level planning can be used to determine information including (but not limited to) the types of behavior that systems should consistently perform, the scene elements that should be considered relevant and when, and/or the actions that should obtain system attention. High-level plans may make considerations including but not limited to dynamic agents in the environment and prospective common scenarios for autonomous mobile robots. When high-level plans have been developed, corresponding low-level actions (i.e., on-the-spot responses to immediate stimuli) may be guided by smaller subsets of scene elements (e.g., present lane curvature, distance to the leading vehicle).

Processes for training autonomous navigation systems can avoid the computational strain of simulation environments by limiting the simulation of sensory data. As a result, processes for training autonomous navigation systems in accordance with numerous embodiments of the invention instead utilize priors reflective of present assessments made by the autonomous navigation system and/or updated as new sensory data comes in. “High-level” priors used by simulations may be directed to capture aspects of the real world that are accurately represented in simulation environments. The aspects of the real world determined to be accurately represented in the simulation environments may then be used to determine and/or update system parameters. As such, in accordance with many embodiments, priors may be determined based on previous data, previous system calculations, and/or baseline assumptions about the parameters. Additionally or alternatively, priors may be combined with real world sensory input, enabling simulations to be updated more computationally efficiently.

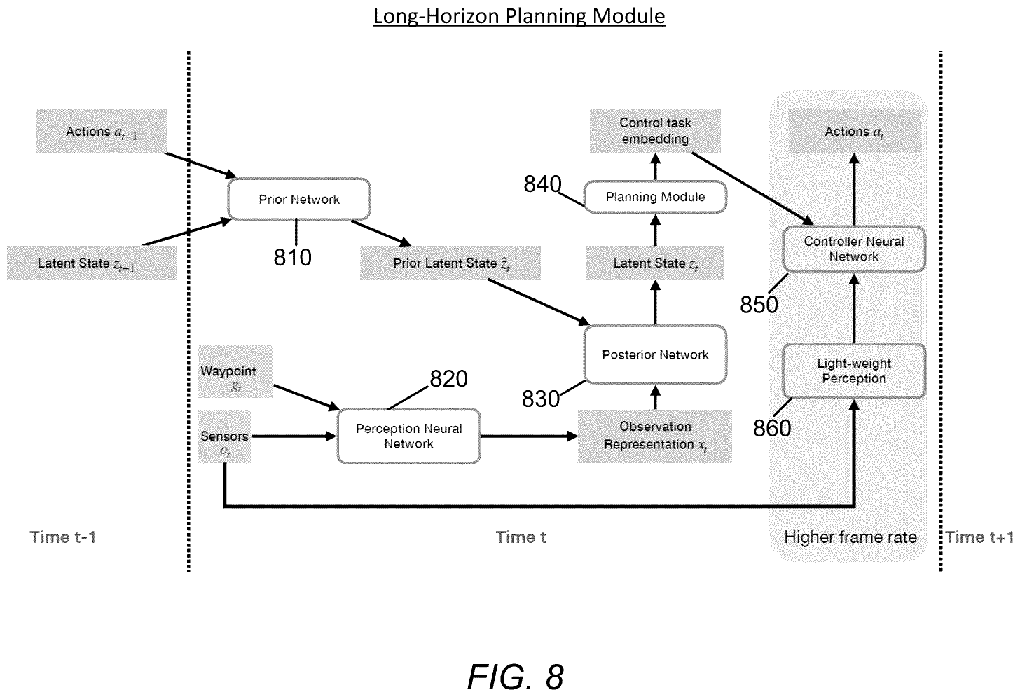

An example of long-horizon-directed neural network architecture utilized by systems configured in accordance with multiple embodiments of the invention is illustrated in FIG. 8. As indicated above, zₜ may reflect system representations of the present state of the environment surrounding an autonomous mobile robot at time step t. In accordance with a number of embodiments of the invention, latent states, as assessed by high-level planners, may be updated through the use of neural networks. Specifically, systems may utilize neural networks applied specifically to updating latent states (e.g. a prior network 810). A prior network 810 can be trained to accept as inputs at least one previous latent state (zₜ₋₁) and/or at least one action (aₜ₋₁) previously performed by the system. The prior network 810 is trained to output a prediction of the current latent state (\hat{z}ₜ).

In several embodiments, perception neural networks 820 are used to derive observation representations (xₜ) of the current features of the surrounding environment including (but not limited to) using any of the planner-driven perception processes described above. Observation representations may correspond to mid-to-high-level visual features that may be learned by systems operating in accordance with a few embodiments of the invention. High-level features may include but are not limited to neurons that are active for particular objects. Such objects may include but are not limited to vehicles, pedestrians, strollers, and traffic lights. Mid-level features may include but are not limited to neurons that can activate for particular shapes, textures, and/or object parts (e.g. car tires, red planar regions, green grassy textures).

In accordance with some embodiments, perception neural networks 820 may receive as inputs navigation waypoints and/or sensor observations (oₜ) to produce the observation representations (xₜ) of the present environment. Neural networks such as (but not limited to) a posterior network 830 can be used to derive the current latent state (zₜ) from inputs including (but not limited to) observation representations (xₜ) and a predicted latent state (\hat{z}ₜ).

Determining high-level plans may involve, but is not limited to, the generation of long-horizon plans. In accordance with many embodiments of the invention, long-horizon planning may refer to situations wherein where autonomous mobile robots plan over many time steps into the future. Such planning may involve an autonomous navigation system determining long-term plans by depending on action-selection strategies and/or policies. Situations where policies are not fixed (control tasks) may see autonomous navigation systems driven by the objective to develop optimal policies. In accordance with certain embodiments of the invention, long-horizon plans may be based on factors including but not limited to the decomposition of the plan's control task into sequences of short-horizon (i.e., short-term) space control tasks, for which situational responses can be determined.

In accordance with many embodiments of the invention, high-level planning modules 840 may be configured to convert the control tasks into embeddings that can be carried out based on the current latent state. The embeddings may be consumed as input by neural networks including but not limited to controller neural networks 850.

Additionally or alternatively, controller neural networks 850 may input sensor observations oₜ and/or low-level observation representations to produce system actions (aₜ). The use of embeddings, sensor observations oₜ, and/or low-level observation representations may allow controller neural networks 850 operating in accordance with numerous embodiments of the invention to run at higher frame rates than when the planning module 840 alone is used to produce system actions. In accordance with some embodiments, low-level observation representations may be produced by limiting the perception neural network 820 output to the first few layers. Additionally or alternatively, sensor observations oₜ, may be input into light-weight perception networks 860 to produce the observation representations. The resulting low-level observation representations may thereby be consumed as inputs by the controller neural network 850.

In accordance with some embodiments, control task specifications can be made more interpretable by including masks into the embeddings, wherein the mask can be applied to the low-level observation representations. In accordance with many embodiments, masks may be used to increase the interpretability of various tasks. Systems operating in accordance with a number of embodiments may establish visualizations of masks. Such visualizations may enable, but are not limited to, analysis of system attention at particular time points of task execution and/or disregard of image portions where system attention may be minimal (i.e., system distractions). Additionally or alternatively, embeddings may incorporate softmax variables that encode distributions over preset numbers (K) of learned control tasks. In such cases, K may be preset at times including but not limited to the point at which models are trained.

As indicated above, the use of embeddings and/or low-level observation representations may enable controller neural networks 850 to run in less computationally intensive manners. High-level planners operating in accordance with a number of embodiments may thereby have high frame rates, bandwidth, and/or system efficiency.

### (b) Domain Adaptation Architectures

Systems in accordance with some embodiments of the invention, when initiating conversions to the reality domain, may be configured to limit latent state space models to learned manifolds determined during the simulation stage. In particular, autonomous navigation systems may project their latent state onto manifolds at run-time, avoiding errors from latent states offset and/or exceeding established boundaries.

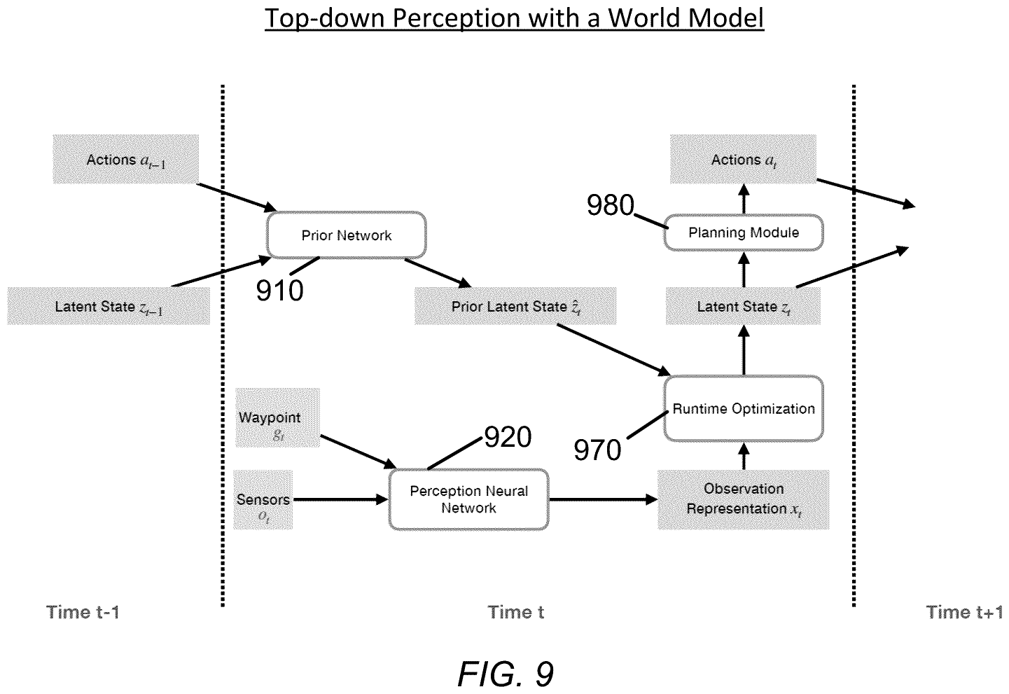

A neural network architecture configured in accordance with some embodiments of the invention, as applied to runtime optimization, is illustrated in FIG. 9. Systems and methods in accordance with numerous embodiments of the invention may impose priors (\hat{z}ₜ) on real world sensor observations (oₜ). Imposition of priors (\hat{z}ₜ) may involve but is not limited to utilizing run-time optimization 970 with energy functions. Energy functions may measure compatibility between data including but not limited to the observation representations (xₜ) and predicted latent states (\hat{z}ₜ). As such, run-time optimizers 970 may take \hat{z}ₜ and xₜ as input and, utilizing an objective function, output an optimal latent state (zₜ) when certain levels of compatibility are met.

At run-time, latent states zₜ may be computed using run-time optimization 970. Optimal values reached at the end of the run-time optimization 970 may represent how well the latent state space models understand the situations in which they operate. Optimal values falling beneath pre-determined thresholds may be interpreted as the models understanding their current situation/environment. Additionally or alternatively, values exceeding the threshold may lead systems to fall back to conservative safety systems.

In performing run-time optimizations, systems may generate objective functions that can be used to derive optimized latent states and/or calibrate operation thresholds for simulation-to-real world (sim-to-real) transfers. Specifically, in accordance with certain embodiments of the invention, run-time optimizers 970 may use objective functions to derive latent states that maximize compatibility with both observation representations (xₜ) and prior latent states (\hat{z}ₜ). Objective functions configured in accordance with numerous embodiments of the invention may be the sum of two or more energy functions. Additionally or alternatively, energy functions may be parameterized as deep neural networks and/or may include, but are not limited to prior energy functions and observation energy functions. Prior energy functions may measure the likelihood that the real latent state is zₜ when it is estimated to be \hat{z}ₜ. Observation energy functions may measure the likelihood that the latent state is z when the observation representation is xₜ. In accordance with numerous embodiments, an example of an objective function may be:

$${z}_{t} = {argmin}_{z} {E}_{pred} ( {\hat{z}}_{t} , z ) + {E}_{obs} ( z , {x}_{t} )$$

where E_{pred}(\hat{z}ₜ, z) is the prior energy function and E_{obs}(z, xₜ) is the observation energy function. One or more energy functions may be parameterized as deep neural networks.

Autonomous navigation systems in accordance with many embodiments of the invention utilize latent state space models that are trained to comply with multiple goals including but not limited to: (1) maximizing downstream rewards of the mobility tasks to be performed, and (2) minimizing the energy objectives (i.e., maximizing correctness) when performing the mobility tasks. Additionally or alternatively, systems may implement one or more regularizers to prevent overfitting. In accordance with many embodiments of the invention, energy functions with particular observed and/or estimated inputs (e.g., \hat{z}ₜ, xₜ) may assess inferred values, assigning low energies when the remaining variables are assigned correct/appropriate values, and higher energies to the incorrect values. In doing so, systems may utilize techniques including but not limited to contrastive self-supervised learning to train latent state space models. When contrastive self-supervised learning is utilized, contrastive terms may be used to increase the energy for time-mismatched input pairs. In instances when latent states zₜ are paired with observations that are coming from different time steps x′ₜ, systems may train auto-increases in energy.

In accordance with a number of embodiments of the invention latent state space models may be fine-tuned in transfers from sim-to-real. In particular, models may optimize parameters that explain state observations, including but not limited to parameters of energy models E_{obs}, and/or perception neural networks 920. Additionally or alternatively, systems may be configured to keep all other parameters fixed. In such cases, high-level priors may be captured near-exactly as they would be in simulation, while parameters that explain the state observations are exclusively allowed to change. In accordance with numerous embodiments, downstream reward optimizations may be disregarded in transfers to reality.

While specific processes are described above for implementing a planner within an autonomous navigation system with reference to FIGS. 5-9, any of a variety of processes can be utilized to determine actions based upon sensor input as appropriate to the requirements of specific applications in accordance with various embodiments of the invention. Furthermore, the described processes are not limited to use within autonomous navigation systems. Accordingly, it should be appreciated that the planner architectures described herein can also be implemented outside the context of an autonomous navigation systems described above with reference to FIGS. 5-9. The manner in which sim-to-real transfers can be performed when training autonomous navigation systems in accordance with various embodiments of the invention is discussed further below.

### D. Sim-to-Real Transfers

Situations where system policies are not fixed (i.e., control tasks) may see systems driven by the objective to develop an optimal policy. In accordance with various embodiments of the invention, systems may learn how to perform control tasks through being trained in simulations and/or having the knowledge transferred to the real world and the physical vehicle (sim-to-real).

In many cases, developed simulations may generate imperfect manifestations of reality (sim-to-real gaps). Systems may be directed to erasing gaps in transfers simulated domains to real domains, thereby producing domain-independent mechanisms. Systems and methods configured in accordance with a number of embodiments of the invention may minimize sim-to-real gaps by projecting real world observations into the same latent spaces as those learned in simulation. Projections of real-world observations into latent spaces may include, but are not limited to the use of unsupervised learning using offline data.

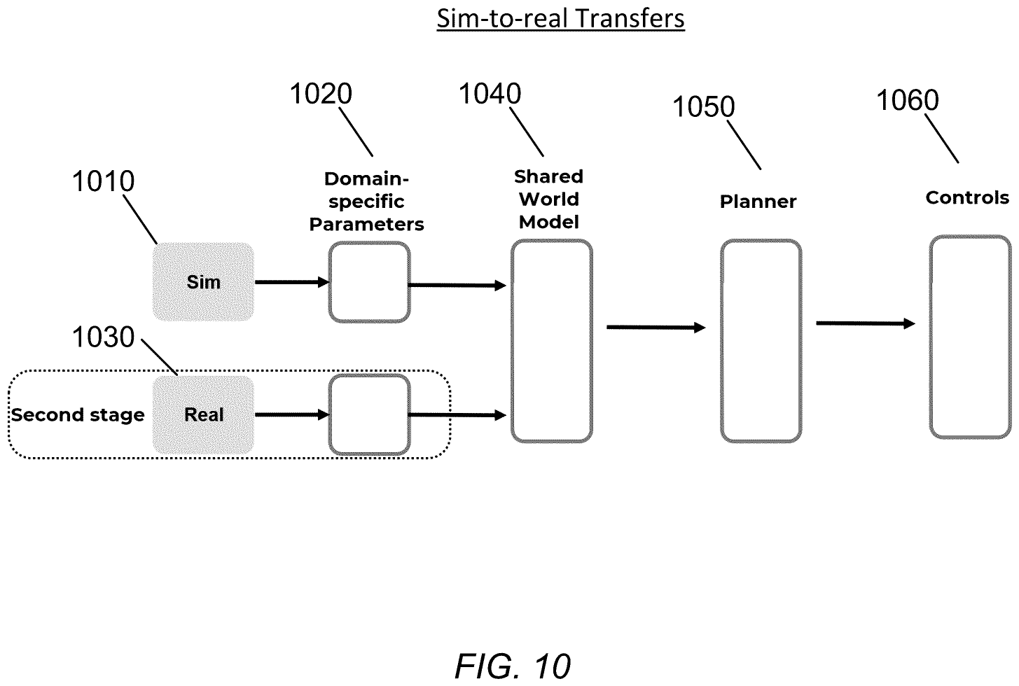

A conceptual diagram of a sim-to-real transfer performed in accordance with several embodiments of the invention is illustrated in FIG. 10. Systems may learn task-relevant latent state spaces by incorporating domain-specific parameters 1020 from simulations 1010 and observation encoders eventually directed to sensory input. The observation encoders may be configured to apply world modeling loss terms and learning processes including but not limited to reinforcement learning in simulation and/or imitation learning in simulation. In doing so, the collection of task-relevant latent state spaces may be used to train world models 1040. Additionally or alternatively, observation encoders may be fine-tuned on offline data taken from real-world 1030 sources. The fine-tuning process may be directed to minimize world modeling loss terms without modifying the world model 1040 itself.

Systems may, additionally or alternatively, apply the trained world models 1050 to system planners and/or controls 1060 to adapt the models to the real world as described above. In adapting world models 1050, systems may collect adaptational data in the real domain. Adaptational data may be obtained through methods including but not limited to teleoperation and/or human-driven platforms.

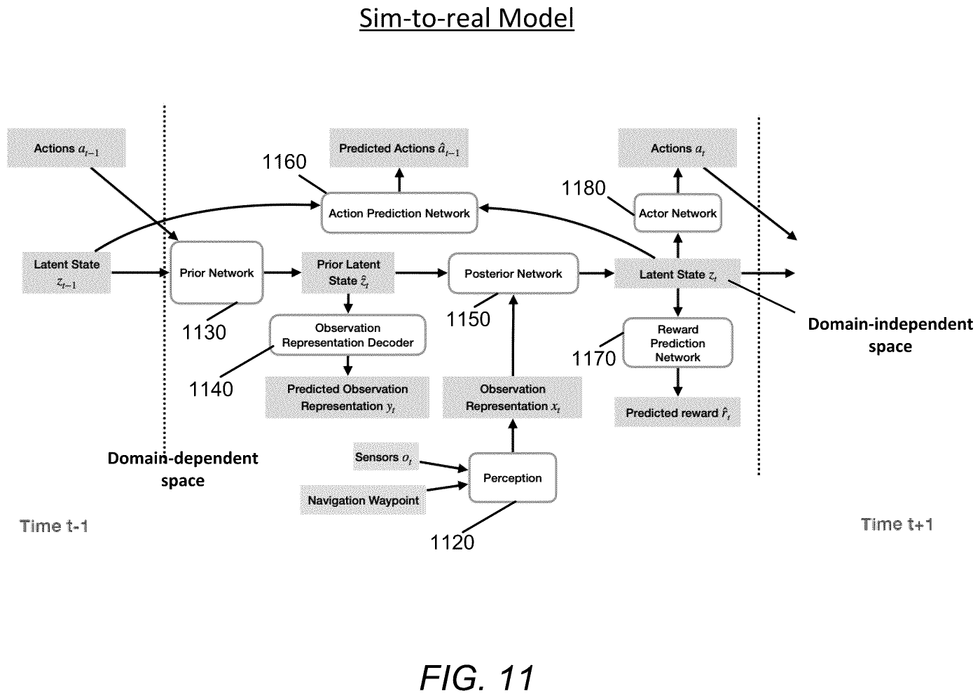

A conceptual diagram of a sim-to-real system operating in accordance with some embodiments of the invention is illustrated in FIG. 11. In a number of embodiments, the problem of sim-to-real transfer may be modeled as a Partially Observable Markov Decision Process (POMDP) with observation space O, action space A, and reward r∈ [symbol] . In several embodiments, a recurrent neural network may be utilized that operates on a sequence of sensor observations oₜ's and navigation goal waypoints gₜ and outputs a sequence of actions aₜ. The recurrent neural network model maintains a latent state zₜ and the overall autonomous navigation system can be defined as follows:

| | |
|---|---|
| Perception 1120 | xₜ = f_{θ}(oₜ, gₜ), |
| Prior Network 1130 | p(\hat{z}ₜ\|zₜ₋₁, aₜ₋₁), |
| Observation Representation Decoder 1140 | yₜ = g(\hat{z}ₜ), |
| Posterior Network 1150 | q(zₜ\|\hat{z}ₜ, xₜ), |
| Action Prediction Network 1160 | âₜ₋₁ = a(zₜ, zₜ₋₁), |
| Reward Prediction Network 1170 | \hat{r}ₜ = r(zₜ) |
| Action Network 1180 | π(a\|zₜ), |
| Critic Networks | Qᵢ(z, a) = i ϵ {0,1}. |

The model is trained in simulation using a Soft Actor Critic (SAC) based approach. The critic loss is modified to include additional world modelling terms.

In a number of embodiments a SAC process is utilized in which the critic loss minimizes the following Bellman residual:

$${J}_{Q} = {( Q ( {z}_{t} , {a}_{t} ) - ( {r}_{t} + γ \overline{Q} ( {z}_{t + 1} , {a}^{′} ) ) )}^{2}$$

where a′=argmaxₐπ(a|zₜ) and Q̅ is the target critic function which is an exponentially moving average of Q. The world model can be trained concurrently by adding the following terms to J_{Q}:

| | | |
|---|---|---|
| Forward Prediction Loss | L_{fwd} | KL(zₜ\|\|\hat{z}ₜ), |
| Action Prediction Loss | L_{action} | \|\|aₜ - âₜ\|\|², |
| Contrastive Loss | L_{contrastive} | $\frac{exp ( λ {x}_{t}^{T} {y}_{t} )}{{\sum }_{t ′} exp ( λ {x}_{t}^{T} {y}_{t} )} ,$ |
| Reward Prediction Loss | L_{reward} | \|\|rₜ - \hat{r}ₜ\|\|². |

where λ is a learned inverse temperature parameter.

Let J_{W} represent a weighted sum of these losses. Then the proposed critic loss function is J_{Q}+J_{W}.

After the model is trained, the model can be adapted to operate in the real world. In several embodiments, this adaptation involves collecting some data in the real domain, which can be done either using teleoperation or directly via a human-driven platform. The notation D={oₜ, aₜ}^{T}ₜ₌₀ to can be used to represent the collected real-world data and the following adaptation loss function defined

$${L}_{action} = {L}_{fwd} + {L}_{action} + {L}_{contrastive}$$

This loss function is minimized on the dataset D over only the perception model parameters

$${θ}_{real} = {argmin}_{θ} {L}_{adapt}$$

The minimization can be done using standard gradient descent-based optimizers. The trained model can then be deployed in an autonomous navigation system for use in the real world using the adapted perception model parameters θᵣₑₐₗ and keeping all other parameters the same as optimized during simulation training.

While specific processes are described above for utilizing simulations to train planners for use in real world autonomous navigation, any of a variety of processes can be utilized as appropriate to the requirements of specific applications in accordance with various embodiments of the invention. Furthermore, systems and methods in accordance with various embodiments of the invention are not limited to use within autonomous navigation systems. Accordingly, it should be appreciated that the sim-to-real transfer mechanisms described herein can also be implemented outside the context of an autonomous navigation system described above with reference to FIGS. 10-11.

While the above description contains many specific embodiments of the invention, these should not be construed as limitations on the scope of the invention, but rather as an example of one embodiment thereof. Accordingly, the scope of the inventions described herein should be determined based upon the specific embodiments illustrated.

What is claimed is:

1. A system for navigation, the system comprising:
a processor;
memory accessible by the processor; and
instructions stored in the memory that when executed by the processor direct the processor to:
obtain, from a plurality of sensors, a set of sensor data;
input the set of sensor data obtained from the plurality of sensors into at least one convolutional neural network (CNN), wherein:
the at least one CNN generates a plurality of key-value pairs; and
for each key-value pair from the plurality of key-value pairs:
the key-value pair corresponds to an individual sensor from the plurality of sensors; and
a value included in the key-value pair is determined based upon a subset of sensor data, from the set of sensor data, wherein the subset of sensor data was obtained from the individual sensor;
retrieve at least one navigation query;
input the at least one navigation query and the plurality of key-value pairs into a Cross-Attention Transformer (CAT);
obtain, from the CAT, a set of weighted sums, wherein each weighted sum from the set of weighted sums corresponds to:
a certain key-value pair from the plurality of key-value pairs; and
a certain sensor from the plurality of sensors;
update a model based on the set of weighted sums, wherein the model depicts a three-dimensional (3D) environment surrounding the system; and
navigate the system within the 3D environment according, at least in part, to the model.

2. The system of claim 1, wherein, for each key-value pair from the plurality of key-value pairs, the key-value pair further corresponds to a particular location within the 3D environment.

3. The system of claim 1, wherein a sensor of the plurality of sensors is selected from the group consisting of: an inertial measurement unit (IMU), an inertial navigation system (INS), a global navigation satellite system (GNSS), a camera, a proximity sensor, and a light detection and ranging system (LiDAR).

4. The system of claim 1, wherein:
the plurality of sensors comprises at least one camera;
the plurality of sensors obtains the set of sensor data from a plurality of perspectives; and
the set of sensor data comprises an accumulated image.

5. The system of claim 4, wherein generating the plurality of key-value pairs comprises:
calibrating the at least one camera;
deriving a positional embedding from the calibration and a patch, wherein the patch comprises a subsection of the accumulated image;
obtaining, from the at least one CNN, an output feature representation; and
concatenating the positional embedding and the output feature representation.

6. The system of claim 1, wherein the system is an autonomous vehicle.

7. The system of claim 1, wherein the at least one navigation query comprises at least one of:
a first query, wherein the first query represents a static two-dimensional grid depicting a first subarea of the 3D environment; or
a second query, wherein the second query represents a static three-dimensional grid depicting a second subarea of the 3D environment.

8. The system of claim 7, wherein updating the model comprises at least one of:
identifying potential obstacles that could impede navigation using the first query; or
localizing subsets of the second subarea that are occupied using the second query.

9. The system of claim 1, wherein inputting the at least one navigation query and the plurality of key-value pairs into the CAT comprises converting the at least one navigation query into a query input using a temporal self-attention transformer.

10. The system of claim 1, wherein:
updating the model based on the set of weighted sums comprises deriving, from the set of weighted sums a set of depth estimates corresponding to the 3D environment; and
deriving, from the set of depth estimates, a depth map for the 3D environment.

11. A method for navigation, the method comprising:
obtaining, from a plurality of sensors, a set of sensor data;
input the set of sensor data obtained from the plurality of sensors into at least one convolutional neural network (CNN), wherein:
the at least one CNN generates a plurality of key-value pairs; and
for each key-value pair from the plurality of key-value pairs:
the key-value pair corresponds to an individual sensor from the plurality of sensors; and
a value included in the key-value pair is determined based upon a subset of sensor data, from the set of sensor data, wherein the subset of sensor data was obtained from the individual sensor;
retrieving at least one navigation query;
inputting the at least one navigation query and the plurality of key-value pairs into a Cross-Attention Transformer (CAT);
obtaining, from the CAT, a set of weighted sums, wherein each weighted sum from the set of weighted sums corresponds to:
a certain key-value pair from the plurality of key-value pairs; and
a certain sensor from the plurality of sensors;
updating a model based on the set of weighted sums, wherein the model depicts a three-dimensional (3D) environment surrounding a system; and
navigating the system within the 3D environment according, at least in part, to the model.

12. The method of claim 11, wherein, for each key-value pair from the plurality of key-value pairs, the key-value pair corresponds to a particular location within the 3D environment.

13. The method of claim 11, wherein a sensor of the plurality of sensors is selected from the group consisting of: an inertial measurement unit (IMU), an inertial navigation system (INS), a global navigation satellite system (GNSS), a camera, a proximity sensor, and a light detection and ranging (LiDAR) system.

14. The method of claim 11, wherein:
the plurality of sensors comprises at least one camera;
the plurality of sensors obtains the set of sensor data from a plurality of perspectives; and
the set of sensor data comprises an accumulated image.

15. The method of claim 14, wherein generating the plurality of key-value pairs comprises:
calibrating the at least one camera;
deriving a positional embedding from the calibration and a patch, wherein the patch comprises a subsection of the accumulated image;
obtaining, from the at least one CNN, an output feature representation; and
concatenating the positional embedding and the output feature representation.

16. The method of claim 11, wherein the system is an autonomous vehicle.

17. The method of claim 11, wherein the at least one navigation query comprises at least one of:
a first query, wherein the first query represents a static two-dimensional grid depicting a first subarea of the 3D environment; or
a second query, wherein the second query represents a static three-dimensional grid depicting a second subarea of the 3D environment.

18. The method of claim 17, wherein updating the model comprises at least one of:
identifying potential obstacles that could impede navigation using the first query; or
localizing subsets of the second subarea that are occupied using the second query.

19. The method of claim 11, wherein inputting the at least one navigation query and the plurality of key-value pairs into the CAT comprises converting the at least one navigation query into a query input using a temporal self-attention transformer.

20. The method of claim 11, wherein:
updating the model based on the set of weighted sums comprises deriving, from the set of weighted sums a set of depth estimates corresponding to the 3D environment; and
deriving, from the set of depth estimates, a depth map for the 3D environment.
